(19) United States
(12) Patent Application Publication
(10) Pub. No.: US 2026/0344034 A1
(43) Pub. Date: Oct. 29, 2026

(54) SEMICONDUCTOR DEVICE INCLUDING A GATE ELECTRODE AND METHOD OF FABRICATING THE SAME

(71) Applicant: Samsung Electronics Co., Ltd., Suwon-si (KR)

(72) Inventor: Sungmin KIM, Suwon-si (KR)

(73) Assignee: Samsung Electronics Co., Ltd., Suwon-si (KR)

(21) Appl. No.: 19/450,337

(22) Filed: Jan. 15, 2026

(30) Foreign Application Priority Data
Apr. 24, 2025 (KR) 10-2025-0053894

(51) Int. Cl. H10D 84/85; H10D 84/01

(52) U.S. Cl. CPC H10D 84/852; H10D 84/0167; H10D 84/017; H10D 84/0172; H10D 84/0188

(57) ABSTRACT

A semiconductor device may include first source/drain patterns extending in a first direction on a substrate and spaced apart from each other in a second direction, a first gate electrode between the first source/drain patterns, a first active pattern penetrating the first gate electrode in the second direction and being connected with the first source/drain patterns, second source/drain patterns spaced apart from the first source/drain patterns in a third direction, a second gate electrode between the second source/drain patterns and spaced apart from the first gate electrode in the third direction, and a second active pattern connected with the second source/drain patterns and penetrating the second gate electrode in the second direction. A first side surface of the first gate electrode in the third direction and a second side surface of the second gate electrode in the third direction each may include a facet surface.

### CROSS-REFERENCE TO RELATED APPLICATIONS

This application claims the benefit of Korean Patent Application No. 10-2025-0053894, filed on Apr. 24, 2025 in the Korean Intellectual Property Office, the disclosure of which is incorporated herein by reference in its entirety.

### BACKGROUND

### 1. Field

Example embodiments relate to a semiconductor device and/or a method of manufacturing the same.

### 2. Description of the Related Art

As one of the scaling technologies for increasing the density of integrated circuit devices, proposed is a multi-gate transistor that forms a fin-shaped or nanowire-shaped silicon body on a substrate and forms a gate on the surface of the silicon body.

Meanwhile structures that separate adjacent gates may be required as semiconductor devices become more highly integrated. As the design rules of semiconductor devices decrease, the difficulty of the process of forming the structure that separates the gate may increase.

### SUMMARY

An aspect provides a highly integrated semiconductor device.

Another aspect provides a semiconductor device in which reliability may be improved.

Another aspect provides a method of manufacturing a semiconductor device for which difficulty of the manufacturing process may be lowered.

The technical tasks to be achieved by the present example embodiments are not limited to the technical tasks described above, and other technical tasks may be inferred from the following example embodiments by those skilled in the art.

According to an aspect, a semiconductor device may include a plurality of first source/drain patterns on a substrate in a first direction and being spaced apart from each other in a second direction, the first direction intersecting an upper surface of the substrate and the second direction intersecting the first direction; a first gate electrode between the plurality of first source/drain patterns; a first active pattern penetrating the first gate electrode in the second direction, the first active pattern being connected with the plurality of first source/drain patterns; a plurality of second source/drain patterns spaced apart from the plurality of first source/drain patterns in a third direction, the third direction intersecting the first direction and the second direction; a second gate electrode spaced apart from the first gate electrode in the third direction, the second gate electrode being between the plurality of second source/drain patterns in the second direction; and a second active pattern penetrating the second gate electrode in the second direction, the second active pattern being connected with the plurality of second source/drain patterns, wherein a first side surface of the first gate electrode in the third direction and a second side surface of the second gate electrode in the third direction each may include a facet surface.

According to another aspect, a semiconductor device may include a first active pattern over a substrate in a first direction, the first direction intersecting an upper surface of the substrate, the first active pattern extending in a second direction, the second direction intersecting the first direction; a first gate electrode surrounding at least a portion of the first active pattern; a second active pattern over the substrate in the first direction, the second active pattern being spaced apart from the first active pattern in a third direction, the third direction intersecting the first direction and the second direction; a second gate electrode spaced apart from the first gate electrode in the third direction and surrounding at least a portion of the second active pattern; and a gate separation structure between the first gate electrode and the second gate electrode in the third direction, wherein the first gate electrode may include a first lower portion pattern and a first upper portion pattern on the first lower portion pattern, the first lower portion pattern may surround the first active pattern and may protrude outward from a center of the first active pattern in the third direction, a width of the first upper portion pattern in the third direction may increase as the first upper portion pattern gets farther from the first lower portion pattern in the first direction, the second gate electrode may include a second lower portion pattern and a second upper portion pattern on the second lower portion pattern, the second lower portion pattern may surround the second active pattern and may protrude outward from a center of the second active pattern in the third direction, and a width of the second upper portion pattern in the third direction may increase as the second upper portion pattern gets farther from the second lower portion pattern in the first direction.

According to another aspect, a semiconductor device may include a plurality of first source/drain patterns on a substrate in a first direction and being spaced apart from each other in a second direction, the first direction intersecting an upper surface of the substrate, and the second direction intersecting the first direction; a first gate electrode between the plurality of first source/drain patterns in the second direction; a first gate insulation film surrounding a lower surface of the first gate electrode and a side surface of the first gate electrode; a first active pattern penetrating the first gate electrode in the second direction, the first active pattern being connected with the plurality of first source/drain patterns; a plurality of second source/drain patterns spaced apart from the plurality of first source/drain patterns in a third direction, the third direction intersecting the first direction and the second direction; a second gate electrode spaced apart from the first gate electrode in the third direction, the second gate electrode being between the plurality of second source/drain patterns in the second direction; a second gate insulation film surrounding a lower surface of the second gate electrode and a side surface of the second gate electrode; and a second active pattern penetrating the second gate electrode in the second direction, the second active pattern being connected with the plurality of second source/drain patterns, wherein a first side surface of the first gate electrode in the third direction and a second side surface of the second gate electrode in the third direction each may include a facet surface having a (100) crystal plane.

According to another aspect, a method of manufacturing a semiconductor device may include alternately laminating a first sacrificial film and a first active pattern on a substrate in a first direction, the first direction intersecting an upper surface of the substrate, to provide a plurality of first sacrificial films and a plurality of first active patterns alternately stacked on the substrate; forming a plurality of first source/drain patterns that are connected with the plurality of first sacrificial films and the plurality of first active patterns in a second direction, the second direction intersecting the first direction, the plurality of first source/drain patterns being spaced apart from each other in the second direction; forming a first epitaxial pattern between the plurality of first source/drain patterns that surround the plurality of first sacrificial films and the plurality of first active patterns; forming an interlayer insulation film covering the first epitaxial pattern; forming a first gate electrode trench in the interlayer insulation film by removing the first epitaxial pattern and the plurality of first sacrificial films, and forming a first gate insulation film and a first gate electrode in the first gate electrode trench.

Specific details of other example embodiments are included in the detailed description and drawings.

### BRIEF DESCRIPTION OF THE FIGURES

These and/or other aspects, features, and advantages of inventive concepts will become apparent and more readily appreciated from the following description of example embodiments, taken in conjunction with the accompanying drawings of which:

FIG. 1 is a drawing illustrating a schematic layout of a semiconductor device according to an example embodiment;

FIG. 2 is a drawing illustrating a cross-section taken along line A-A′ of FIG. 1;

FIG. 3 is a drawing illustrating a cross-section taken along line B-B′ of FIG. 1;

FIG. 4 is a drawing illustrating an enlarged view of a part A of FIG. 3;

FIG. 5 is a drawing illustrating a cross-section taken along line C-C′ of FIG. 1;

FIG. 6 to FIG. 9 are cross-sectional views taken along line B-B′ of FIG. 1 to illustrate semiconductor devices according to an example embodiment;

FIG. 10 is a cross-sectional view taken along line A-A′ of FIG. 1 to illustrate a semiconductor device according to an example embodiment;

FIG. 11 is a drawing illustrating a cross-section along line B-B′ of FIG. 1 to illustrate a semiconductor device according to an example embodiment;

FIG. 12 is a cross-sectional view taken along line B-B′ of FIG. 1 to illustrate a semiconductor device according to an example embodiment;

FIG. 13 to FIG. 34 are drawings illustrating intermediate operations for explaining a method of manufacturing the semiconductor device illustrated in FIG. 2 and FIG. 3, according to an example embodiment; and

FIG. 35 to FIG. 45 are drawings illustrating intermediate operations for explaining a method for manufacturing a semiconductor device illustrated in FIG. 9, according to an example embodiment.

### DETAILED DESCRIPTION

In the detailed description of the present disclosure, terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain embodiments of inventive concepts in the best way. The example embodiments described in this specification and the configurations shown in the drawings are only the presented embodiments of the present disclosure, and do not necessarily represent the entire technical idea of the present disclosure. Accordingly, at the time of filing the present disclosure, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

In the present disclosure, terms “first,” “second” and so on may be used to describe various components. However, the components are not limited by the terms, and the terms may be used for the purpose of distinguishing one component from another. Within the scope of the technical idea of the present disclosure, the first component may be named as the second component. Similarly, the second component may also be named the first component. Further, the shape and size of components may be exaggerated to emphasize clear explanation.

Further, in the following description, expressions such as an upper side, top, a lower side, bottom, a side, front, and a back side are expressed based on the direction shown in the drawing. If the direction of the object changes, it may be expressed differently. The shapes and sizes of elements in the drawings may be exaggerated for clearer explanation.

Regarding semiconductor devices according to some example embodiments, drawings illustrate a fin-type transistor (FinFET) including a channel region in the shape of a fin-shape pattern, transistor including nanowire or nano sheets, and multi-bridge channel field effect transistor (MBCFET). However, the present disclosure is not limited thereto.

According to some example embodiments, the semiconductor device may include a tunneling transistor (tunneling FET), a three-dimensional (3D) transistor, or a vertical transistor (Vertical FET). According to some example embodiments, it is apparent that semiconductor devices may include planar transistors. In addition, the technical idea of the present disclosure may be applied to a transistor based on two-dimensional (2D) material (2D material based FETs) and its heterostructure. Further, according to some example embodiments, semiconductor devices may include bipolar junction transistors, lateral double-diffused transistors (LDMOS) and so on.

Hereinafter, example embodiments according to the technical idea of the present disclosure will be described with reference to the attached drawings.

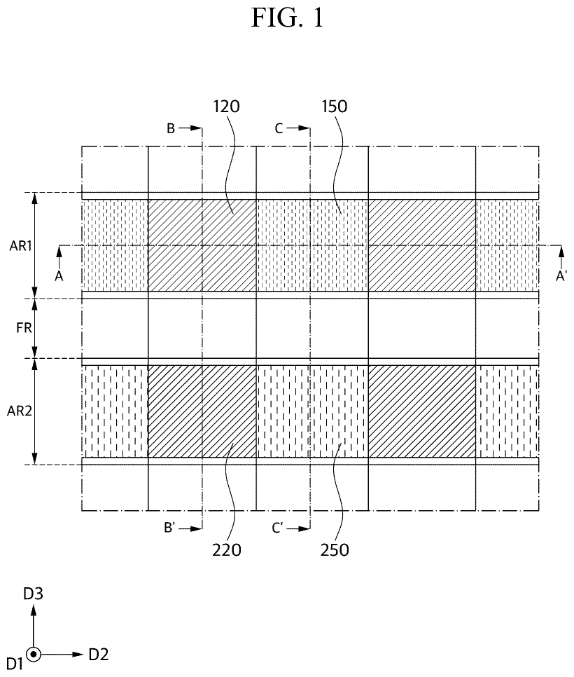

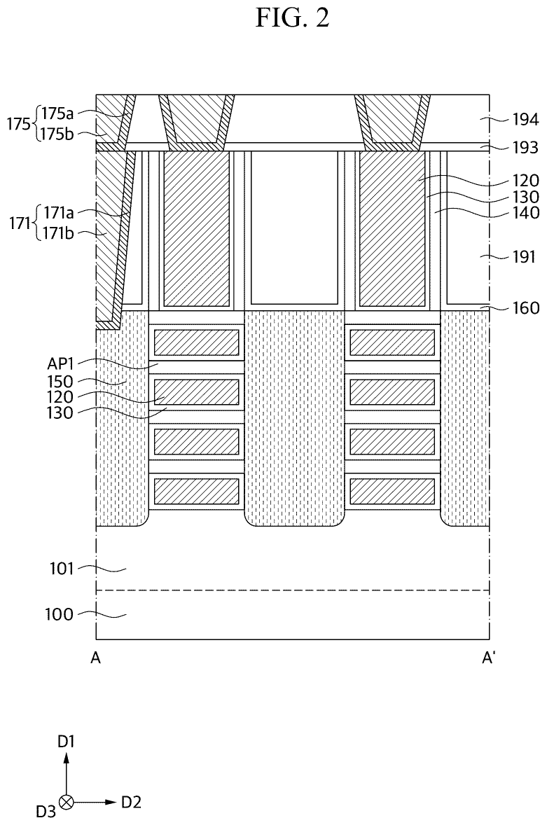

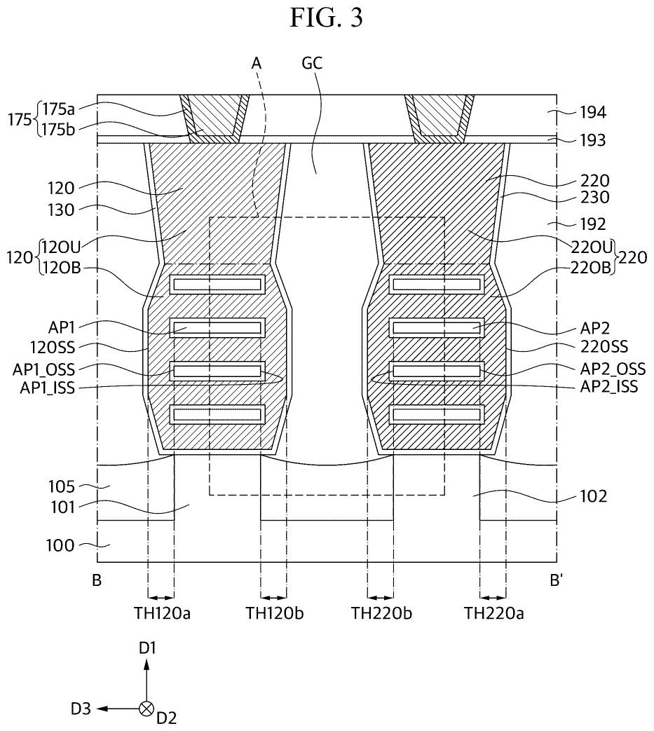

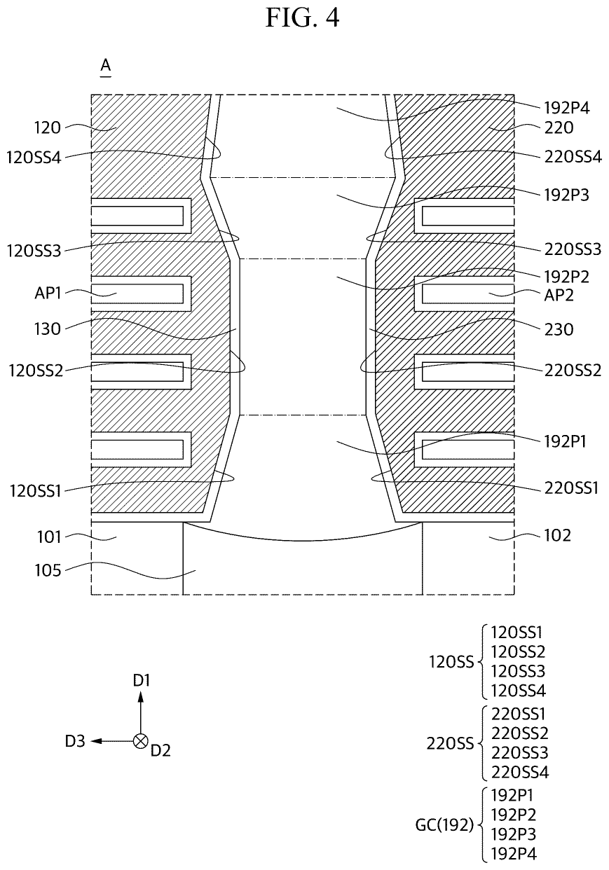

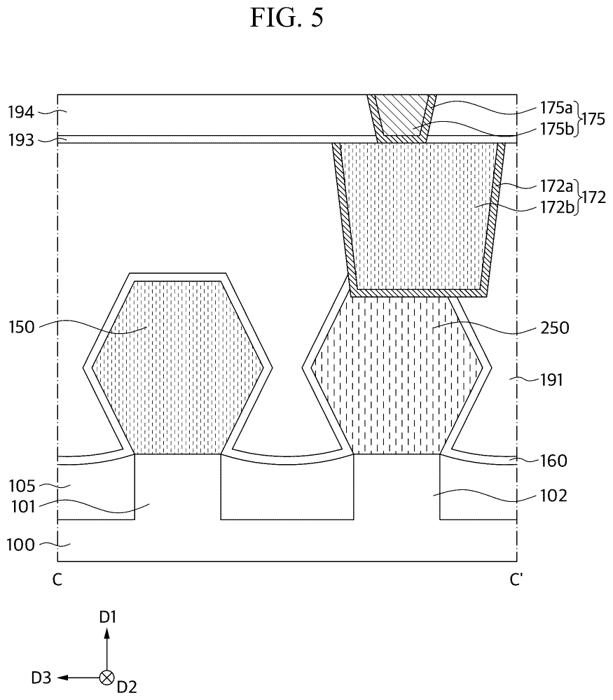

FIG. 1 is a drawing illustrating a schematic layout of a semiconductor device according to an example embodiment. FIG. 2 is a drawing illustrating a cross-section taken along line A-A′ of FIG. 1. FIG. 3 is a drawing illustrating a cross-section taken along line B-B′ of FIG. 1. FIG. 4 is a drawing illustrating an enlarged view of a part A of FIG. 3. FIG. 5 is a drawing illustrating a cross-section taken along line C-C′ of FIG. 1.

Referring to FIG. 1 to FIG. 5, according to some example embodiments, a semiconductor device may include a substrate 100, a first active pattern AP1, a second active pattern AP2, a first gate electrode 120, a second gate electrode 220, a first source/drain pattern 150, a second source/drain pattern 250, and a gate separation structure GC.

According to some example embodiments, the substrate 100 may include a first active region AR1, a second active region AR2, and a field region FR. Each of the first active region AR1, the second active region AR2 and the field region FR may be extended in the second direction D2. The first active region AR1, the second active region AR2 and the field region FR may be placed alternately in the third direction D3. For example, the first active region AR1 may be placed between field regions FR in the third direction D3. The field region FR may be placed between the first active region AR1 and the second active region AR2 in the third direction D3. Here, each of the second direction D2 and the third direction D3 may refer to a direction parallel to the substrate 100 and intersecting the first direction D1. The first direction D1 may refer to a direction intersecting the surface of the substrate 100. For example, the first direction D1 may refer to a direction intersecting the upper surface of the substrate 100. The second direction D2 may refer to the direction along which the first active region AR1, the second active region AR2, and the field region FR extend. The third direction D3 may refer to a direction in which the first active region AR1, the field region FR, and the second active region AR2 are placed alternately.

According to some example embodiments, the field region FR may be defined by a trench, but is not limited thereto. Further, a person skilled in the art may distinguish which part is a field region and which part is an active region. The field region FR may have a shallow trench isolation (STI) structure. However, example embodiments are not limited thereto. For example, in some embodiments, the field region FR may be defined by a deep trench.

According to some example embodiments, a device isolation film may be placed around the first active region AR1 and the second active region AR2, which are spaced apart from each other. Here, a portion between the adjacent first active region AR1 and the second active region AR2 in the device isolation film may be the field region FR. For example, a part where the channel region of a transistor, which may be an example of a semiconductor device, is formed may be the active region, and a part that separates the channel region of the transistor formed in the active region may be a field region. Alternatively, an active region may be the part where a fin-shaped pattern or nano sheet is formed, which is used as the channel region of the transistor, and a field region may be a region where a fin-shaped pattern or nano sheet is not formed, which is used as a channel region.

According to some example embodiments, the substrate 100 may be a semiconductor or semiconductor-on-insulator. For example, the substrate 100 may be bulk silicon or silicon-on-insulator (SOI). Alternatively, the substrate 100 may be a silicon substrate, or may include other materials such as silicon germanium, silicon germanium on insulator (SGOI), indium antimonide, lead telluride, indium arsenide, indium phosphide, gallium arsenide and gallium antimonide. However, the substrate 100 is not limited thereto.

According to some example embodiments, the substrate 100 may include an insulating material. For example, the substrate 100 may include at least one of silicon oxide (SiO₂), silicon nitride (SiN), silicon oxynitride (SiON), silicon oxycarbide (SiOC), silicon carbonitride (SiCN), and silicon oxycarbonitride (SiOCN).

FIG. 2, FIG. 3 and FIG. 5 illustrate that the substrate 100 is placed under a first fin-shape pattern 101 and a second fin-shape pattern 102, but example embodiments are not limited thereto. For example, the substrate 100 may not be placed under the first fin-shape pattern 101 and the second fin-shape pattern 102. In the process of manufacturing semiconductor devices according to some example embodiments, the substrate 100 positioned under the first fin-shape pattern 101 and the second fin-shape pattern 102 may be removed. In another example embodiment, the first fin-shape pattern 101 and the substrate 100 may not be placed below the first gate electrode 120 and the first source/drain pattern 150, and the second fin-shape pattern 102 and the substrate 100 may not be placed under the second gate electrode 220 and the second source/drain pattern 250. In the process of manufacturing semiconductor devices according to some example embodiments, the first fin-shape pattern 101, the second fin-shape pattern 102 and the substrate 100 placed under the first gate electrode 120, the first source/drain pattern 150, the second gate electrode 220 and the second source/drain pattern 250 may be removed, and an interlayer insulation film may be formed.

According to some example embodiments, the first fin-shape pattern 101 may be placed on the first active region AR1 of the substrate 100. The second fin-shape pattern 102 may be placed on the second active region AR2 of the substrate 100. Each of the first fin-shape pattern 101 and the second fin-shape pattern 102 may protrude from the substrate 100. Each of the first fin-shape pattern 101 and the second fin-shape pattern 102 may be extended along the second direction D2. Each of the first fin-shape pattern 101 and the second fin-shape pattern 102 may be formed by etching a portion of the substrate 100, or may include an epitaxial layer grown from the substrate 100.

According to some example embodiments, each of the first fin-shape pattern 101 and the second fin-shape pattern 102 may include silicon (Si). In another example embodiment, each of the first fin-shape pattern 101 and the second fin-shape pattern 102 may include a compound semiconductor. For example, each of the first fin-shape pattern 101 and the second fin-shape pattern 102 may include a group IV-IV compound semiconductor or a group III-V compound semiconductor. For example, IV-IV group compound semiconductors may be binary compounds, ternary compounds containing at least two of carbon (C), silicon (Si), germanium (Ge) and tin (Sn), or compounds doped with group IV elements. For example, a III-V compound semiconductor may be a binary compound, a ternary compound, or a quaternary compound formed by combining at least one of the group III elements aluminum (Al), gallium (Ga), and indium (In) with one of the group V elements phosphorus (P), arsenic (As) and antimony (Sb). For example, each of the first fin-shape pattern 101 and the second fin-shape pattern 102 may include a semiconductor material. The first fin-shape pattern 101 and the second fin-shape pattern 102 may include one of the elementary semiconductor materials, silicon or germanium, a group IV-IV compound semiconductor, or a group III-V compound semiconductor.

According to some example embodiments, each of the first fin-shape pattern 101 and the second fin-shape pattern 102 may include an insulating material. For example, each of the first fin-shape pattern 101 and the second fin-shape pattern 102 may include at least one of silicon oxide (SiO₂), silicon nitride (SiN), silicon oxynitride (SiON), silicon carbonitride (SiCN), silicon oxycarbide (SiOC) and silicon oxycarbonitride (SiOCN).

According to some example embodiments, the first active pattern AP1 may be placed on the first active region AR1 of the substrate 100. The first active pattern AP1 may be placed on the first fin-shape pattern 101. For example, the first active pattern AP1 may be an active pattern including a nano sheet or nanowire. The first active pattern AP1 may contain a plurality of first sheets. The plurality of first sheets may be placed on the substrate 100. The plurality of first sheets may be placed to be spaced apart from the substrate 100 in the first direction D1. The plurality of first sheets may be placed to be spaced apart from each other in the first direction D1. The plurality of first sheets may be extended along the second direction D2.

According to some example embodiments, the first active pattern AP1 may include a first inner side AP1_ISS and a first outer side AP1_OSS that are spaced apart in the third direction D3. The first inner side AP1_ISS may face the second active pattern AP2 in the third direction D3. The first outer side AP1_OSS may be placed on the side opposite to the first inner side AP1_ISS in the third direction D3.

According to some example embodiments, a plurality of first active patterns AP1 may be placed. The plurality of first active patterns AP1 may be placed to be spaced apart in the second direction D2. For example, the plurality of first active patterns AP1 may be placed to be spaced apart from each other in the second direction D2 in the first active region AR1 that extends along the second direction D2.

According to some example embodiments, in the second direction D2, the first active pattern AP1 may be placed between the first source/drain patterns 150. The first active pattern AP1 may be connected to the first source/drain pattern 150 in the second direction D2. The first active pattern AP1 may extend along the second direction D2 and penetrate the first gate electrode 120. The first active pattern AP1 may be surrounded by the first gate electrode 120.

According to some example embodiments, the second active pattern AP2 may be placed on the second active region AR2 of the substrate 100. The second active pattern AP2 may be placed on the second fin-shape pattern 102. For example, the second active pattern AP2 may be an active pattern including a nano sheet or nanowire. The second active pattern AP2 may contain a plurality of second sheets. The plurality of second sheets may be placed on the substrate 100. The plurality of second sheets may be placed to be spaced apart from the substrate 100 in the first direction D1. The plurality of second sheets may be placed to be spaced apart from each other in the first direction D1. The plurality of second sheets may be extended along the second direction D2.

According to some example embodiments, the second active pattern AP2 may include a second inner side AP2_ISS and a second outer side AP2_OSS spaced apart in the third direction D3. The second inner side AP2_ISS may face the first active pattern AP1 in the third direction D3. The second outer side AP2_OSS may be placed on the side opposite to the second inner side AP2_ISS in the third direction D3.

According to some example embodiments, a plurality of second active patterns AP2 may be placed. The plurality of second active patterns AP2 may be placed to be spaced apart in the second direction D2. For example, the plurality of second active patterns AP2 may be placed to be spaced apart in the second direction D2 in the second active region AR2 extending along the second direction D2.

According to some example embodiments, in the second direction D2, the second active pattern AP2 may be placed between the second source/drain pattern 250. The second active pattern AP2 may be connected to the second source/drain pattern 250 in the second direction D2. The second active pattern AP2 may extend along the second direction D2 and penetrate the second gate electrode 220. The second active pattern AP2 may be surrounded by the second gate electrode 220.

For example, the width of the plurality of first sheets of the first active pattern AP1 in the third direction D3 may be increased or decreased in proportion to the width of the first fin-shape pattern 101 placed at the lower portion of the first active pattern AP1 in the third direction D3. The width of the plurality of second sheets of the second active pattern AP2 in the third direction D3 may be increased or decreased in proportion to the width of the second fin-shape pattern 102 placed at the lower portion of the second active pattern AP2 in the third direction D3.

According to some example embodiments, the first active pattern AP1 and the second active pattern AP2 may be placed spaced apart in the third direction D3. The first active pattern AP1 and the second active pattern AP2 may be spaced apart from each other in the third direction D3 with the gate separation structure GC interposed therebetween.

According to some example embodiments, the first active pattern AP1 and the second active pattern AP2 may include, for example, an elementary semiconductor material such as silicon or germanium. Further, the first active pattern AP1 and the second active pattern AP2 may include a compound semiconductor, and the first active pattern AP1 and the second active pattern AP2 may include, for example, a group IV-IV compound semiconductor or a group III-V compound semiconductor.

The IV-IV group compound semiconductor may be a binary compound, a ternary compound, or a compound doped with a group IV element, containing at least two of, for example, carbon (C), silicon (Si), germanium (Ge) and tin (Sn).

A III-V group compound semiconductor may be, for example, a group III element, and may be one of a binary compound, a ternary compound, or a quaternary compound formed by combining at least one of aluminum (Al), gallium (Ga), and indium (In) with one of group V elements phosphorus (P), arsenic (As) and antimony (Sb).

According to some example embodiments, each of the first active pattern AP1 and the second active pattern AP2 may include the same material as the first fin-shape pattern 101 and the second fin-shape pattern 102, and may include a material different from the first fin-shape pattern 101 and the second fin-shape pattern 102. The first fin-shape pattern 101 and the second fin-shape pattern 102 may be silicon fin-shape patterns containing silicon, and the first active pattern AP1 and the second active pattern AP2 may be silicon sheet patterns including silicon. Each of the first active pattern AP1 and the second active pattern AP2 may not contain P-type impurities or N-type impurities. The first active pattern AP1 and the second active pattern AP2 may contain only silicon.

FIG. 2 and FIG. 3 illustrate that the semiconductor device of the present disclosure includes a multi-bridge channel field effect transistor (MBCFET) by each of the first active pattern AP1 and the second active pattern AP2 including four first sheets and four second sheets. However, the present disclosure is not limited thereto. It is apparent that the semiconductor device of the present disclosure may include a fin-type transistor (FinFET) by the first active pattern AP1 and the second active pattern AP2 not including nano sheets, but by the first active pattern AP1 and the second active pattern AP2 including only fin-shaped patterns extending along the second direction D2 and protruding from the substrate 100 in the first direction D1.

According to some example embodiments, a device isolation film 105 may be placed in the field region FR. The device isolation film 105 may be disposed on the substrate 100. The device isolation film 105 may be placed at the bottom of the gate separation structure GC. For example, the device isolation film 105 may be positioned between the first fin-shape pattern 101 and the second fin-shape pattern 102 spaced apart in the third direction D3. The device isolation film 105 may be placed on the substrate 100 so that the first active pattern AP1 and the second active pattern AP2 do not overlap in the first direction D1. The device isolation film 105 may be placed between the first active pattern AP1 and the second active pattern AP2 in the third direction D3. The device isolation film 105 may fill at least a portion of the trench formed on the substrate 100.

According to some example embodiments, the device isolation film 105 may cover the side surfaces of the first fin-shape pattern 101 and the second fin-shape pattern 102. The upper surface of the device isolation film 105 may be positioned lower than the upper surfaces of the first fin-shape pattern 101 and the second fin-shape pattern 102. Unlike what is illustrated, the upper surface of the device isolation film 105 may be placed in the same plane as the upper surfaces of the first fin-shape pattern 101 and the second fin-shape pattern 102. The device isolation film 105 may cover only a portion of the side surfaces of the first fin-shape pattern 101 and the second fin-shape pattern 102. In such a case, a portion of the first fin-shape pattern 101 and the second fin-shape pattern 102 may protrude in the first direction D1 beyond the device isolation film 105. For example, the device isolation film 105 may include an oxide film, a nitride film, an oxynitride film, or a combination thereof. The device isolation film 105 is depicted as a single film, but it is only for convenience of explanation, and the device isolation film 105 is not limited thereto.

According to some example embodiments, the first gate electrode 120 may be placed on the first active region AR1 of the substrate 100. The first gate electrode 120 may be placed on the first fin-shape pattern 101. The first gate electrode 120 may be placed to be spaced apart in the second direction D2 on the first active region AR1 of the substrate 100.

According to some example embodiments, the first gate electrode 120 may be placed between the first source/drain patterns 150 that are adjacent to each other in the second direction D2. In the second direction D2, the first gate electrode 120 may be placed on both sides of the first source/drain pattern 150. In an example embodiment, the first gate electrodes 120 placed on both sides of the first source/drain pattern 150 may both be normal gate electrodes used as gates of the transistor. In another example embodiment, even though the first gate electrode 120, located on one side of the first source/drain pattern 150, is used as the gate of the transistor, the first gate electrode 120 placed on the other side of the first source/drain pattern 150 may be a dummy gate electrode.

According to some example embodiments, the first gate electrode 120 may be penetrated by the first active pattern AP1 extending along the second direction D2. The first gate electrode 120 may surround the first active pattern AP1. The first gate electrode 120 may surround at least a portion of the first active pattern AP1. For example, the first gate electrode 120 may surround the outer surfaces of the first active pattern AP1 except for the side surface of the first active pattern AP1 that is connected to the first source/drain pattern 150. The first gate electrode 120 may surround a plurality of first sheets of the first active pattern AP1.

According to some example embodiments, a portion of the first gate electrode 120 may be placed between a plurality of first sheets of adjacent first active pattern AP1 in the first direction D1. A portion of the first gate electrode 120 may be placed on the top first sheet among the plurality of first sheets of the first active pattern AP1.

According to some example embodiments, the first gate electrode 120 may include a first lower portion pattern 120B and a first upper portion pattern 120U. The first lower portion pattern 120B and the first upper portion pattern 120U may be connected in the first direction D1. The first lower portion pattern 120B may be placed on the first fin-shape pattern 101. The first upper portion pattern 120U may be placed on the first lower portion pattern 120B.

According to some example embodiments, the first lower portion pattern 120B may surround the first active pattern AP1. The first lower portion pattern 120B may be protruded outwardly based on the center of the first active pattern AP1 in the third direction D3. For example, the side surface of the first lower portion pattern 120B in the third direction D3 may have a convex profile with respect to the side surface of the first active pattern AP1 in the third direction D3 (the first inner side AP1_ISS, the first outer side AP1_OSS). The width along the third direction D3 of the first lower portion pattern 120B may increase and then decrease again in the first direction D1 as the first lower portion pattern 120B gets farther away from the substrate 100.

According to some example embodiments, the first upper portion pattern 120U may penetrate at least a portion of a second interlayer insulation film 192. The first upper portion pattern 120U may have a width that increases in the third direction D3 as the first upper portion pattern 120U gets farther away from the first lower portion pattern 120B in the first direction D1.

According to some example embodiments, a first side surface 120SS in the third direction D3 of the first gate electrode 120 may include a facet surface. Specifically, the side surface of the first lower portion pattern 120B in the third direction D3 may include a facet surface. The first side surface 120SS may refer to the side surface of the first gate electrode 120, which is spaced apart in the third direction D3. For example, the first side surface 120SS may include one side of the first gate electrode 120 facing the second gate electrode 220 in the third direction D3, and may include the other side of the first gate electrode 120 placed on the side opposite to the one side of the first gate electrode 120 in the third direction D3.

According to some example embodiments, at least a portion of the facet surface of the first side surface 120SS of the first gate electrode 120 may be aligned with a crystal plane of the substrate 100. At least a portion of the first side surface of the facet surface120SS of the first gate electrode 120 being aligned with the crystal plane of the substrate 100 may indicate that at least a portion of the facet surface of the first side surface 120SS of the first gate electrode 120 matching the direction of the crystal plane of the substrate 100. For example, when the substrate 100 has a (110) crystal plane or a (100) crystal plane, and when the notch of the substrate 100 has a [100] crystal direction, at least a portion of the facet surface of the first side surface 120SS of the first gate electrode 120 may be aligned with the (100) crystal plane. In another example embodiment, when the substrate 100 has a (100) crystal plane and the notch of the substrate 100 has a [110] crystal direction, at least a portion of the facet surface of the first side surface 120SS of the first gate electrode 120 may be aligned with the (111) crystal plane. At least a portion of a region of the facet surface of the first side surface 120SS of the first gate electrode 120 may be aligned with a crystal plane of a plurality of first source/drain patterns 150 or a plurality of second source/drain patterns 250.

According to some example embodiments, the first side surface 120SS may include a first sub-side surface 120SS1, a second sub-side surface 120SS2, a third sub-side surface 120SS3 and a fourth sub-side surface 120SS4. The first sub-side surface 120SS1, the second sub-side surface 120SS2 and the third sub-side surface 120SS3 may be facet surfaces of the first lower portion pattern 120B. The fourth sub-side surface 120SS4 may be the side surface of the first upper portion pattern 120U. The first sub-side surface 120SS1, the second sub-side surface 120SS2, the third sub-side surface 120SS3 and the fourth sub-side surface 120SS4 may be connected to each other.

According to some example embodiments, the first sub-side surface 120SS1 of the first side surface 120SS may be connected to the lower surface of the first lower portion pattern 120B. The first sub-side surface 120SS1 of the first side surface 120SS may be the bottom facet surface of the first side surface 120SS. The first sub-side surface 120SS1 of the first side surface 120SS may be a facet surface that gets farther away from the first active pattern AP1 in the third direction D3 as the facet surface gets farther away from the first fin-shape pattern 101 in the first direction D1. For example, the first sub-side surface 120SS1 of the first side surface 120SS may be aligned with the (111) crystal plane.

According to some example embodiments, the second sub-side surface 120SS2 of the first side surface 120SS may be connected to the first sub-side surface 120SS1 of the first side surface 120SS. The second sub-side surface 120SS2 of the first side surface 120SS may be a facet surface of which distance from the first active pattern AP1 in the third direction D3 is constant as the facet surface gets farther away from the first fin-shape pattern 101 in the first direction D1. For example, the second sub-side surface 120SS2 of the first side surface 120SS may be aligned with the (100) crystal plane. The second sub-side surface 120SS2 of the first side surface 120SS may be parallel in the first direction D1.

According to some example embodiments, the third sub-side surface 120SS3 of the first side surface 120SS may be connected to the second sub-side surface 120SS2 of the first side surface 120SS. The third sub-side surface 120SS3 of the first side surface 120SS may be a facet surface that gets closer to the first active pattern AP1 in the third direction D3 as the facet surface gets farther away from the first fin-shape pattern 101 in the first direction D1. For example, the third sub-side surface 120SS3 of the first side surface 120SS may be aligned with the (111) crystal plane.

According to some example embodiments, the fourth sub-side surface 120SS4 of the first side surface 120SS may be connected to the third sub-side surface 120SS3 of the first side surface 120SS. The fourth sub-side surface 120SS4 of the first side surface 120SS may be connected to the third sub-side surface 120SS3 of the first side surface 120SS. The fourth sub-side surface 120SS4 of the first side surface 120SS may be the top facet surface of the first side surface 120SS. The fourth sub-side surface 120SS4 of the first side surface 120SS may be a facet surface that gets closer to the second gate electrode 220 in the third direction D3 as the facet surface gets farther away from the first fin-shape pattern 101 in the first direction D1.

According to some example embodiments, the first gate electrode 120 may have a symmetrical structure in the third direction D3 with respect to the center of the first active pattern AP1 in the third direction D3. For example, the thickness TH120a in the third direction D3 of a part of the first gate electrode 120 placed on the first outer side AP1_OSS in the third direction D3 and the thickness TH120b in the third direction D3 of a part of the first gate electrode 120 placed on the first inner side AP1_ISS in the third direction D3 may be the same. The thickness TH120a along the third direction of a part of the first gate electrode 120 placed on the first outer side AP1_OSS in the third direction D3 may be the thickness of the thickest part of the first gate electrode 120 in the third direction D3 based on the first outer side AP1_OSS. The thickness TH120b in the third direction D3 of a part of the first gate electrode 120 placed on the first inner side AP1_ISS in the third direction D3 may be the thickness of the thickest part of the first gate electrode 120 in the third direction D3 based on the first inner side AP1_ISS. The distance in the third direction D3 between the first side surface 120SS and the first outer side AP1_OSS, placed on the opposite side to the second gate electrode 220, may be equal to the distance in the third direction D3 between the first side surface 120SS and the first inner side AP1_ISS facing the second gate electrode 220.

According to some example embodiments, the second gate electrode 220 may be disposed on the second active region AR2 of the substrate 100. The second gate electrode 220 may be placed on the second fin-shape pattern 102. The second gate electrode 220 may be placed spaced apart in the second direction D2 on the second active region AR2 of the substrate 100.

According to some example embodiments, the second gate electrode 220 may be placed between adjacent second source/drain patterns 250 in the second direction D2. In the second direction D2, the second gate electrode 220 may be placed on both sides of the second source/drain pattern 250. In an example embodiment, the second gate electrodes 220 placed on both sides of the second source/drain pattern 250 may both be normal gate electrodes used as gates of the transistor. In another example embodiment, even though the second gate electrode 220, located on one side of the second source/drain pattern 250, is used as the gate of the transistor, the second gate electrode 220 placed on the other side of the second source/drain pattern 250 may be a dummy gate electrode.

According to some example embodiments, the second gate electrode 220 may be penetrated by the second active pattern AP2 extending along the second direction D2. The second gate electrode 220 may surround the second active pattern AP2. The second gate electrode 220 may surround at least a portion of the second active pattern AP2. For example, the second gate electrode 220 may surround the outer surfaces of the second active pattern AP2 excluding the side surface of the second active pattern AP2 that is connected to the second source/drain pattern 250. The second gate electrode 220 may surround a plurality of second sheets of the second active pattern AP2.

According to some example embodiments, a portion of the second gate electrode 220 may be placed between the plurality of second sheets of the second active pattern AP2 adjacent in the first direction D1. A portion of the second gate electrode 220 may be disposed on the top second sheet among the plurality of second sheets of the second active pattern AP2.

According to some example embodiments, the second gate electrode 220 may include a second lower portion pattern 220B and a second upper portion pattern 220U. The second lower portion pattern 220B and the second upper portion pattern 220U may be connected in the first direction D1. The second lower portion pattern 220B may be placed on the second fin-shape pattern 102. The second upper portion pattern 220U may be placed on the second lower portion pattern 220B.

According to some example embodiments, the second lower portion pattern 220B may surround the second active pattern AP2. The second lower portion pattern 220B may protrude outwardly based on the center of the second active pattern AP2 in the third direction D3. For example, the side surface of the second lower portion pattern 220B in the third direction D3 may have a convex profile with respect to the side surface of the second active pattern AP2 in the third direction D3 (the second inner side AP2_ISS, the second outer side AP2_OSS). The width in the third direction D3 of the second lower portion pattern 220B may increase and then decrease again as the second lower portion pattern 220B gets farther from the substrate 100 in the first direction D1.

According to some example embodiments, the second upper portion pattern 220U may penetrate at least a portion of the second interlayer insulation film 192. The second upper portion pattern 220U may have a width that increases in the third direction D3 as the second upper portion pattern 220U gets farther from the second lower portion pattern 220B in the first direction D1.

According to some example embodiments, a second side surface 220SS in the third direction D3 of the second gate electrode 220 may include a facet surface. Specifically, the side surface of the second lower portion pattern 220B in the third direction D3 may include a facet surface. The second side surface 220SS may refer to the side surface of the second gate electrode 220 spaced apart in the third direction D3. For example, the second side surface 220SS may include one side of the second gate electrode 220 facing the first gate electrode 120 in the third direction D3, and may include the other side of the second gate electrode 220 that is placed on the side opposite to the one side of the second electrode 220 in the third direction D3.

According to some example embodiments, at least a portion of the facet surface of the second side surface 220SS of the second gate electrode 220 may match the crystal plane of the substrate 100. For example, when the substrate 100 has a (110) crystal plane or a (100) crystal plane, and the notch of the substrate 100 has a [100] crystal direction, at least a portion of the facet surface of the second side surface 220SS of the second gate electrode 220 may be aligned with the (100) crystal plane. In another example embodiment, when the substrate 100 has a (100) crystal plane and the notch of the substrate 100 has a [110] crystal direction, at least a portion of the facet surface of the second side surface 220SS of the second gate electrode 220 may be aligned with the (111) crystal plane. At least a portion of the facet surface of the second side surface 220SS of the second gate electrode 220 may be aligned with a crystal plane of a plurality of first source/drain patterns 150 or a plurality of second source/drain patterns 250.

According to some example embodiments, the second side surface 220SS may include a fifth sub-side surface 220SS1, a sixth sub-side surface 220SS2, a seventh sub-side surface 220SS3 and an eighth sub-side surface 220SS4. The fifth sub-side surface 220SS1, the sixth sub-side surface 220SS2 and the seventh sub-side surface 220SS3 may be facet surfaces of the second lower portion pattern 220B. The eighth sub-side surface 220SS4 may be the side surface of the second upper portion pattern 220U. The fifth sub-side surface 220SS1, the sixth sub-side surface 220SS2, the seventh sub-side surface 220SS3 and the eighth sub-side surface 220SS4 may be connected to each other.

According to some example embodiments, the fifth sub-side surface 220SS1 of the second side surface 220SS may be connected to the lower surface of the second lower portion pattern 220B. The fifth sub-side surface 220SS1 of the second side surface 220SS may be the bottom facet surface of the second side surface 220SS. The fifth sub-side surface 220SS1 of the second side surface 220SS may be a facet surface that gets farther away from the second active pattern AP2 in the third direction D3 as the facet surface gets farther away from the second fin-shaped pattern 102 in the first direction D1. For example, the fifth sub-side surface 220SS1 of the second side surface 220SS may be aligned with the (111) crystal plane.

According to some example embodiments, the sixth sub-side surface 220SS2 of the second side surface 220SS may be connected to the fifth sub-side surface 220SS1 of the second side surface 220SS. The sixth sub-side surface 220SS2 of the second side surface 220SS may be a facet surface of which distance from the second active pattern AP2 in the third direction D3 is constant as the facet surface gets farther away from the second fin-shaped pattern 102 in the first direction D1. For example, the sixth sub-side surface 220SS2 of the second side surface 220SS may be aligned with the (100) crystal plane. The sixth sub-side surface 220SS2 of the second side surface 220SS may be parallel in the first direction D1.

According to some example embodiments, the seventh sub-side surface 220SS3 of the second side surface 220SS may be connected to the sixth sub-side surface 220SS2 of the second side surface 220SS. The seventh sub-side surface 220SS3 of the second side surface 220SS may be a facet surface that gets closer to the second active pattern AP2 in the third direction D3 as the facet surface gets farther away from the second fin-shaped pattern 102 in the first direction D1. For example, the seventh sub-side surface 220SS3 of the second side surface 220SS may be aligned with the (111) crystal plane.

According to some example embodiments, the eighth sub-side surface 220SS4 of the second side surface 220SS may be connected to the seventh sub-side surface 220SS3 of the second side surface 220SS. The eighth sub-side surface 220SS4 of the second side surface 220SS may be the top facet surface of the second side surface 220SS. The eighth sub-side surface 220SS4 of the second side surface 220SS may be a facet surface that gets closer to the first gate electrode 120 in the third direction D3 as the facet surface gets farther away from the second fin-shape pattern 102 in the first direction D1.

According to some example embodiments, the second gate electrode 220 may have a symmetrical structure in the third direction D3 with respect to the center of the second active pattern AP2 in the third direction D3. The thickness TH220a in the third direction D3 of a part of the second gate electrode 220 placed on the second outer side AP2_OSS in the third direction D3 and the thickness TH220b in the third direction D3 of a part of the second gate electrode 220 placed on the second inner side AP2_ISS in the third direction D3 may be the same. The thickness TH220a in the third direction D3 of a part of the second gate electrode 220 placed on the second outer side AP2_OSS in the third direction D3 may be the thickness of the thickest part of the second gate electrode 220 in the third direction D3 based on the second outer side AP2_OSS. The thickness TH220b in the third direction D3 of a part of the second gate electrode 220 placed on the second inner side AP2_ISS in the third direction D3 may be the thickness of the thickest part of the second gate electrode 220 in the third direction D3 based on the second inner side AP2_ISS. The distance in the third direction D3 between the second side surface 220SS and the second outer side AP2_OSS placed on the opposite side to the first gate electrode 120 may be the same as the distance in the third direction D3 between the second side surface 220SS and the second inner side AP2_ISS facing the first gate electrode 120.

According to some example embodiments, the width of the first gate electrode 120 in the third direction D3 may be the same as the width of the second gate electrode 220. The distance between the first side surfaces 120SS in the third direction D3 may be the same as the distance between the second side surfaces 220SS in the third direction D3. The thickness TH220a in the third direction D3 of a part of the second gate electrode 220 placed on the second outer side AP2_OSS in the third direction D3 may be the same as the thickness TH120a in the third direction D3 of a part of the first gate electrode 120 placed on the first outer side AP1_OSS in the third direction D3. The thickness TH220b in the third direction D3 of a part of the second gate electrode 220 placed on the second inner side AP2_ISS in the third direction D3 may be the same as the thickness TH120b in the third direction D3 of a part of the first gate electrode 120 placed on the first inner side AP1_ISS in the third direction D3.

According to some example embodiments, each of the first gate electrode 120 and the second gate electrode 220 may include at least one of a metal, a metal alloy, a conductive metal nitride, a metal silicide, a doped semiconductor material, a conductive metal oxide, and a conductive metal oxynitride. For example, the first gate electrode 120 and the second gate electrode 220 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) and combinations thereof. However, the first gate electrode 120 and the second gate electrode 220 are not limited thereto. The conductive metal oxides and conductive metal oxynitrides may include, but are not limited to, oxidized forms of the materials described above.

According to some example embodiments, a first gate insulation film 130 may extend along the upper surface of the first fin-shape pattern 101 and the first side surface 120SS of the first gate electrode 120. The first gate insulation film 130 may extend along the side surface of the first lower portion pattern 120B, the lower surface of the first lower portion pattern 120B, and the side surface of the first upper portion pattern 120U. The first gate insulation film 130 may wrap the first active pattern AP1. The first gate insulation film 130 may surround the first gate electrode 120. The first gate insulation film 130 may be placed along the perimeter of a plurality of first sheets of the first active pattern AP1. The first gate insulation film 130 may be placed between the first gate electrode 120 and the first active pattern AP1. The first gate insulation film 130 may not come into contact with the device isolation film 105. For example, as shown in FIGS. 3-4, a portion of the lower surface of the first gate insulation film 130 may be spaced apart from a portion of the upper surface of the device isolation film 105 therebelow. The first gate insulation film 130 may extend along the side surface of the gate separation structure GC facing the first gate electrode 120. The first gate insulation film 130 may cover the side surface of the gate separation structure GC facing the first gate electrode 120 in the third direction D3.

According to some example embodiments, a second gate insulation film 230 may extend along the upper surface of the second fin-shape pattern 102 and the second side surface 220SS of the second gate electrode 220. The second gate insulation film 230 may extend along the side surface of the second lower portion pattern 220B, the lower surface of the second lower portion pattern 220B, and the side surface of the second upper portion pattern 220U. The second gate insulation film 230 may wrap the second active pattern AP2. The second gate insulation film 230 may surround the second gate electrode 220. The second gate insulation film 230 may be placed along the perimeter of a plurality of second sheets of the second active pattern AP2. The second gate insulation film 230 may be placed between the second gate electrode 220 and the second active pattern AP2. The second gate insulation film 230 may not come into contact with the device isolation film 105. For example, as shown in FIGS. 3-4, a portion of the lower surface of the second gate insulation film 230 may be spaced apart from a portion of the upper surface of the device isolation film 105 therebelow. The second gate insulation film 230 may extend along the side surface of the gate separation structure GC facing the second gate electrode 220. The second gate insulation film 230 may cover the side surface of the gate separation structure GC facing the second gate electrode 220 in the third direction D3.

According to some example embodiments, the first gate insulation film 130 and the second gate insulation film 230 may not be connected to each other. The first gate insulation film 130 and the second gate insulation film 230 may be spaced apart from each other with the gate separation structure GC interposed therebetween.

According to some example embodiments, each of the first gate insulation film 130 and the second gate insulation film 230 may include silicon oxide, silicon-germanium oxide, germanium oxide, silicon oxynitride, silicon nitride, or a high-k material having a dielectric constant greater than silicon oxide. For example, the high-k material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide and lead zinc niobate.

FIG. 2 to FIG. 4 illustrate that each of the first gate insulation film 130 and the second gate insulation film 230 is a single film, but this is for convenience of explanation only and the present disclosure is not limited thereto. Each of the first gate insulation film 130 and the second gate insulation film 230 may include a plurality of films. Each of the first gate insulation film 130 and the second gate insulation film 230 may include an interfacial layer disposed between the first active pattern AP1 or the second active pattern AP2 and the first gate electrode 120 or the second gate electrode 220, and a high-k insulation film.

According to some example embodiments, a semiconductor device may include a negative capacitance (NC) FET using a negative capacitor. For example, the first gate insulation film 130 may include a ferroelectric material film having ferroelectric properties and a paraelectric material film having paraelectric properties.

According to some example embodiments, the ferroelectric material film may have negative capacitance, and the paraelectric material film may have positive capacitance. For example, when two or more capacitors are connected in series and the capacitance of each capacitor has a positive value, the overall capacitance is reduced compared to the capacitance of each individual capacitor. On the other hand, when at least one of the capacitances of two or more capacitors connected in series has a negative value, the total capacitance may be positive and greater than the absolute value of each individual capacitance.

According to some example embodiments, when a ferroelectric material film with negative capacitance and a paraelectric material film with positive capacitance are connected in series, the overall capacitance value of the ferroelectric material films and paraelectric material films connected in series may increase. By taking advantage of the increase in overall capacitance value, transistors containing ferroelectric material films may have a subthreshold swing (SS) of less than 60 mV/decade at room temperature.

According to some example embodiments, the ferroelectric material films may have ferroelectric properties. For example, the ferroelectric material film may include at least one of hafnium oxide, hafnium zirconium oxide, barium strontium titanium oxide, barium titanium oxide, and lead zirconium titanium oxide. Here, in an example embodiment, hafnium zirconium oxide may be a material in which hafnium oxide is doped with zirconium (Zr). In another example embodiment, hafnium zirconium oxide may be a compound of hafnium (Hf), zirconium (Zr), and oxygen (O).

According to some example embodiments, the ferroelectric material film may further contain doped dopants. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). Depending on which ferroelectric material the ferroelectric material film contains, the type of dopant contained in the ferroelectric material film may vary.

According to some example embodiments, when the ferroelectric material film contains hafnium oxide, the dopant included in the ferroelectric material film may include, for example, at least one of gadolinium (Gd), silicon (Si), zirconium (Zr), aluminum (Al) and yttrium (Y).

According to some example embodiments, when the dopant is aluminum (Al), the ferroelectric material film may contain 3 to 8 atomic % aluminum. Here, the ratio of the dopant may be the ratio of aluminum to the sum of hafnium and aluminum.

According to some example embodiments, when the dopant is silicon (Si), the ferroelectric material film may contain 2 to 10 at % silicon. When the dopant is yttrium (Y), the ferroelectric material film may contain 2 to 10 at % yttrium. When the dopant is gadolinium (Gd), the ferroelectric material film may contain 1 to 7 at % gadolinium. When the dopant is zirconium (Zr), the ferroelectric material film may contain 50 to 80 at % zirconium.

According to some example embodiments, the paraelectric material films may have paraelectric properties. For example, the paraelectric material film may include at least one of silicon oxide and a metal oxide having a high-k. For example, the metal oxide included in the paraelectric material film may include at least one of hafnium oxide, zirconium oxide, and aluminum oxide. However, the metal oxide included in the paraelectric material film is not limited thereto.

According to some example embodiments, the ferroelectric material film and the paraelectric material film may contain the same material. A ferroelectric material film may have ferroelectric properties, but a paraelectric material film may not have ferroelectric properties. For example, when the ferroelectric material film and paraelectric material film contain hafnium oxide, the crystal structure of hafnium oxide included in the ferroelectric material film is different from the crystal structure of hafnium oxide included in the paraelectric material film.

According to some example embodiments, the ferroelectric material film may have a thickness that exhibits ferroelectric properties. The thickness of the ferroelectric material film may be, for example, 0.5 to 10 nm, but the thickness is not limited thereto. The threshold thickness that exhibits ferroelectric properties may vary for each ferroelectric material, and thus the thickness of the ferroelectric material film may vary depending on the ferroelectric material.

In an example embodiment, each of the first gate insulation film 130 and the second gate insulation film 230 may include a single ferroelectric material film. In another example embodiment, each of the first gate insulation film 130 and the second gate insulation film 230 may include a plurality of ferroelectric material films that are spaced apart from each other. Each of the first gate insulation film 130 and the second gate insulation film 230 may have a laminated film structure in which a plurality of ferroelectric material films and a plurality of paraelectric material films are alternately laminated.

According to some example embodiments, a gate spacer 140 may be placed on the side surfaces of the first gate electrode 120 and the second gate electrode 220. The gate spacer 140 may not be placed between the first fin-shape pattern 101 and the first active pattern AP1, not be placed between a plurality of first sheets of first active pattern AP1 adjacent to the first direction D1, not be placed between the second fin-shape pattern 102 and the second active pattern AP2, and not be placed between a plurality of second sheets of the second active pattern AP2 adjacent in the first direction D1. However, example embodiments are not limited thereto. For example, the gate spacer 140 may be placed between the first fin-shape pattern 101 and the first active pattern AP1, be placed between a plurality of first sheets of the first active pattern AP1 adjacent in the first direction D1, be placed between the second fin-shape pattern 102 and the second active pattern AP2, and be placed between a plurality of second sheets of the second active pattern AP2 adjacent in the first direction D1.

Even though FIG. 2 only illustrates that the gate spacer 140 is placed on the side surface of the first gate electrode 120, on a cross-section taken along the second direction D2 in the second active region AR2 as illustrated in FIG. 2, the gate spacer 140 may be placed on the side surface of the second gate electrode 220.

According to some example embodiments, the gate spacer 140 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. The gate spacer 140 is illustrated as a single layer, but this is only for convenience of explanation, and the gate spacer 140 is not limited thereto.

According to some example embodiments, the gate separation structure GC may be placed between the first gate electrode 120 and the second gate electrode 220 in the third direction D3. The gate separation structure GC may be placed between the first side surface 120SS of the first gate electrode 120 and the second side surface 220SS of the second gate electrode 220, which face each other in the third direction D3. The gate separation structure GC may be the second interlayer insulation film 192 placed between the first gate electrode 120 and the second gate electrode 220 in the third direction D3. The gate separation structure GC may electrically insulate the first gate electrode 120 and the second gate electrode 220. According to example embodiments, it is possible to improve the integration and reliability of semiconductor devices.

According to some example embodiments, the gate separation structure GC may be positioned between the device isolation film 105, the first gate insulation film 130, and the second gate insulation film 230. The lower surface of the gate separation structure GC may be in contact with the device isolation film 105. The gate separation structure GC may be in contact with the upper surface of the device isolation film 105. The side surface of the gate separation structure GC in the third direction D3 may be covered by the first gate insulation film 130 and the second gate insulation film 230. For example, the side surface of the gate separation structure GC facing the first gate electrode 120 in the third direction D3 may be covered by the first gate insulation film 130, and the side surface of the gate separation structure GC facing the second gate electrode 220 in the third direction D3 may be covered by the second gate insulation film 230.

According to some example embodiments, the gate separation structure GC may include a first part 192P1, a second part 192P2, a third part 192P3 and a fourth part 192P4. The first part 192P1, the second part 192P2, the third part 192P3 and the fourth part 192P4 may be connected to each other in the first direction D1. The first part 192P1, the second part 192P2, the third part 192P3 and the fourth part 192P4 may be sequentially placed in the first direction D1 on the device isolation film 105.

According to some example embodiments, the first part 192P1 may be the lowest region of the gate separation structure GC. For example, the first part 192P1 may include the lower surface of the gate separation structure GC. The first part 192P1 may be placed between the lowest facet surface of the first side surface 120SS and the lowest facet surface of the second side surface 220SS. The first part 192P1 may be placed between the first sub-side surface 120SS1 of the first side surface 120SS and the fifth sub-side surface 220SS1 of the second side surface 220SS. As the first part 192P1 gets farther from the substrate 100 along the first direction D1 between the first gate electrode 120 and the second gate electrode 220 in the third direction D3, the width of the first part 192P1 in the third direction D3 may decrease. This may be due to the facet surface of the first sub-side surface 120SS1 of the first side surface 120SS and the facet surface of the fifth sub-side surface 220SS1 of the second side surface 220SS being tilted toward each other.

According to some example embodiments, the second part 192P2 may be placed on the first part 192P1. The second part 192P2 may be placed between the first part 192P1 and the third part 192P3 in the first direction D1. The second part 192P2 may be placed between the second sub-side surface 120SS2 of the first side surface 120SS and the sixth sub-side surface 220SS2 of the second side surface 220SS. For example, as the second part 192P2 gets farther from the substrate 100 in the first direction D1 between the first gate electrode 120 and the second gate electrode 220 in the third direction D3, the width of the second part 192P2 along the third direction D3 may be constant. This may be due to the fact that the facet surface of the second sub-side surface 120SS2 of the first side surface 120SS and the facet surface of the sixth sub-side surface 220SS2 of the second side surface 220SS are parallel in the first direction D1.

According to some example embodiments, the third part 192P3 may be placed on the second part 192P2. The third part 192P3 may be placed between the second part 192P2 and the fourth part 192P4 in the first direction D1. The third part 192P3 may be placed between the third sub-side surface 120SS3 of the first side surface 120SS and the seventh sub-side surface 220SS3 of the second side surface 220SS. For example, as the third part 192P3 gets farther from the substrate 100 in the first direction D1 between the first gate electrode 120 and the second gate electrode 220 in the third direction D3, the width of the third part 192P3 in the third direction D3 may increase. This may be due to the fact that the facet surface of the third sub-side surface 120SS3 of the first side surface 120SS and the facet surface of the seventh sub-side surface 220SS3 of the second side surface 220SS are tilted toward the first active pattern AP1 and the second active pattern AP2, respectively.

According to some example embodiments, the fourth part 192P4 may be placed on the third part 192P3. The fourth part 192P4 may be placed between the first upper portion pattern 120U and the second upper portion pattern 220U. The fourth part 192P4 may be the top region of the gate separation structure GC. For example, the fourth part 192P4 may include the upper surface of the gate separation structure GC. The fourth part 192P4 may be placed between the top facet surface of the first side surface 120SS and the top facet surface of the second side surface 220SS. The fourth part 192P4 may be placed between the fourth sub-side surface 120SS4 of the first side surface 120SS and the eighth sub-side surface 220SS4 of the second side surface 220SS. As the fourth part 192P4 gets farther from the substrate 100 in the first direction D1 between the first gate electrode 120 and the second gate electrode 220 in the third direction D3, the width of the fourth part 192P4 in the third direction D3 may decrease. This may be due to that the facet surface of the fourth sub-side surface 120SS4 of the first side surface 120SS and the facet surface of the eighth sub-side surface 220SS4 of the second side surface 220SS are tilted toward each other. In other words, since the width of the first upper portion pattern 120U in the third direction D3 increases as the first upper portion pattern 120U gets farther from the substrate 100 along the first direction D1, and since the width of the second upper portion pattern 220U increases in the third direction D3 as the second upper portion pattern 220U gets farther from the substrate 100 in the first direction D1, the fourth part 192P4, which is positioned between the first upper portion pattern 120U and the second upper portion pattern 220U, may have a width that decreases in the third direction D3 as the fourth part 192P4 gets farther from the substrate 100 along the first direction D1.

According to some example embodiments, the gate separation structure GC may include an insulating material. For example, the gate separation structure GC may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. However, example embodiments are not limited thereto.

According to some example embodiments, the first source/drain pattern 150 may be placed in the first active region AR1. The second source/drain pattern 250 may be placed in the second active region AR2. The first source/drain pattern 150 and the second source/drain pattern 250 may be placed in the third direction D3.

According to some example embodiments, the first source/drain pattern 150 and the second source/drain pattern 250 may have different doping types. For example, the first source/drain pattern 150 may have P type, and the second source/drain pattern 250 may have N type. The first source/drain pattern 150 may contain P-type dopants. The P-type dopant may include, but is not limited to, at least one of boron (B) and gallium (Ga). The second source/drain pattern 250 may include N-type dopants. The N-type dopant may include, but is not limited to, at least one of phosphorus (P), arsenic (As), antimony (Sb) and bismuth (Bi). In another example embodiment, the first source/drain pattern 150 may have N type, and the second source/drain pattern 250 may have P type.

According to some example embodiments, the first source/drain pattern 150 may be connected to the first active pattern AP1 in the second direction D2. The first source/drain pattern 150 may be placed between the adjacent first gate electrodes 120 in the second direction D2. The first source/drain pattern 150 may be placed on the first fin-shape pattern 101.

According to some example embodiments, the first source/drain pattern 150 may be the source/drain of a PMOS transistor. The first source/drain pattern 150 may be the source/drain of a transistor that uses the first active pattern AP1 as its channel region.

According to some example embodiments, the second source/drain pattern 250 may be connected to the second active pattern AP2 in the second direction D2. The second source/drain pattern 250 may be placed between adjacent second gate electrodes 220 in the second direction D2. The second source/drain pattern 250 may be placed on the second fin-shape pattern 102.

According to some example embodiments, the second source/drain pattern 250 may be the source/drain of an NMOS transistor. The second source/drain pattern 250 may be the source/drain of a transistor that uses the second active pattern AP2 as its channel region.

According to some example embodiments, a source/drain etching stopping film 160 and a first interlayer insulation film 191 may be disposed on the first source/drain pattern 150 and the second source/drain pattern 250. The source/drain etching stopping film 160 may extend along the upper surfaces of the first source/drain pattern 150 and the second source/drain pattern 250, and the upper surface of the device isolation film 105.

According to some example embodiments, the source/drain etching stopping film 160 may include at least one of silicon nitride (SiN), silicon oxide (SiO₂), silicon oxynitride (SiON), silicon oxycarbonitride (SiOCN), silicon boron nitride (SiBN), silicon oxyboron nitride (SiOBN), silicon oxycarbide (SiOC), and combinations thereof.

According to some example embodiments, the first interlayer insulation film 191 may be disposed on the source/drain etching stopping film 160. The first interlayer insulation film 191 may be formed on the device isolation film 105. In the first direction D1, the first interlayer insulation film 191 may be placed between the first source/drain pattern 150 and the second source/drain pattern 250. The first interlayer insulation film 191 may be placed on the sides of the first source/drain pattern 150 and the second source/drain pattern 250 in the third direction D3.

According to some example embodiments, the second interlayer insulation film 192 may be placed on the sides of the first gate electrode 120 and the second gate electrode 220 in the third direction D3. The second interlayer insulation film 192 may be placed between the first gate electrode 120 and the second gate electrode 220 in the third direction D3. The second interlayer insulation film 192 may form the gate separation structure GC between the first gate electrode 120 and the second gate electrode 220. The second interlayer insulation film 192 may be disposed on the device isolation film 105.

According to some example embodiments, the first interlayer insulation film 191 and the second interlayer insulation film 192 may include at least one of silicon oxide, silicon nitride, silicon oxynitride, and a low-k material. For example, the low-k material may include, but is not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica or combinations thereof.

According to some example embodiments, a first source/drain contact 171 may be placed on the first source/drain pattern 150. The first source/drain contact 171 may be connected to the first source/drain pattern 150. The first source/drain contact 171 may be connected to the first source/drain pattern 150 through the first interlayer insulation film 191 and the source/drain etching stopping film 160. In the first direction D1, the first source/drain contact 171 may completely penetrate the first interlayer insulation film 191.

According to some example embodiments, the first source/drain contact 171 may include a first source/drain contact barrier film 171a and a first source/drain contact filling film 171b surrounded by the first source/drain contact barrier film 171a.

According to some example embodiments, the upper surface of the first source/drain contact barrier film 171a is depicted as being located at substantially the same height as the upper surface of the first source/drain contact filling film 171b, but the upper surface of the first source/drain contact barrier film 171a is not limited thereto. Unlike what is illustrated, the upper surface of the first source/drain contact barrier film 171a may be lower than the upper surface of the first source/drain contact filling film 171b.

According to some example embodiments, the first source/drain contact barrier film 171a may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. According to some example embodiments, in a semiconductor device, the 2D material may be a metallic material and/or a semiconductor material. The 2D material may contain a 2D allotrope or a 2D compound. For example, the 2D material may include at least one of graphene, molybdenum disulfide (MoS2), molybdenum di-selenide (MoSe2), tungsten di-selenide (WSe2), and tungsten disulfide (WS2), but the 2D material is not limited thereto. In other words, the above-described 2D materials are only listed as examples, and therefore, the 2D materials that may be included in the semiconductor device of the present disclosure are not limited by the above-described materials.

According to some example embodiments, the first source/drain contact filling film 171b may include at least one of aluminum (Al), tungsten (W), cobalt (Co), ruthenium (Ru), silver (Ag), gold (Au), manganese (Mn) and molybdenum (Mo).

According to some example embodiments, the first source/drain contact 171 is illustrated to include multiple conductive films, but is not limited thereto. Unlike what is illustrated, it is also apparent that the first source/drain contact 171 is a single film.

According to some example embodiments, a second source/drain contact 172 may be placed on the second source/drain pattern 250. The second source/drain contact 172 may be connected to the second source/drain pattern 250. The second source/drain contact 172 may be connected to the second source/drain pattern 250 through the first interlayer insulation film 191 and the source/drain etching stopping film 160. In the first direction D1, the second source/drain contact 172 may completely penetrate the first interlayer insulation film 191.

According to some example embodiments, the first interlayer insulation film 191 may not cover the upper surfaces of the first source/drain contact 171 and the second source/drain contact 172. In an example embodiment, the upper surface of the first source/drain contact 171 and the upper surface of the second source/drain contact 172 may not protrude higher than the upper surface of the first gate electrode 120 and the upper surface of the second gate electrode 220. The upper surface of the first source/drain contact 171 and the upper surface of the second source/drain contact 172 may be placed on the same plane as the upper surface of the first gate electrode 120 and the upper surface of the second gate electrode 220. Unlike what is illustrated, in another example embodiment, the upper surface of the first source/drain contact 171 and the upper surface of the second source/drain contact 172 may protrude higher than the upper surface of the first gate electrode 120 and the upper surface of the second gate electrode 220.

According to some example embodiments, the second source/drain contact 172 may include a second source/drain contact barrier film 172a, and a second source/drain contact filling film 172b on the second source/drain contact barrier film 172a. The second source/drain contact barrier film 172a may extend along the side surface and the bottom surface of the second source/drain contact filling film 172b. Description on the second source/drain contact barrier film 172a and the second source/drain contact filling film 172b is substantially the same as the description for the first source/drain contact barrier film 171a and the first source/drain contact filling film 171b, and thus the description on the second source/drain contact barrier film 172a and the second source/drain contact filling film 172b is omitted.

According to some example embodiments, a first etching stopping film 193 and a third interlayer insulation film 194 may be disposed on the first interlayer insulation film 191, the second interlayer insulation film 192, the first gate electrode 120, the second gate electrode 220, the first source/drain contact 171, and the second source/drain contact 172. The first etching stopping film 193 and the third interlayer insulation film 194 may be sequentially laminated in the first direction D1.

According to some example embodiments, the first etching stopping film 193 may include a material having an etching selectivity with respect to the third interlayer insulation film 194. The first etching stopping film 193 may include, for example, at least one of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), aluminum oxide (AlO), aluminum nitride (AlN), and aluminum oxycarbide (AlOC) and combinations thereof. The first etching stopping film 193 is illustrated as being a single film, but is not limited thereto. Unlike what is illustrated, the first etching stopping film 193 may not be formed. For example, the third interlayer insulation film 194 may include at least one of silicon oxide, silicon nitride, silicon carbonitride, silicon oxynitride, and a low-k material.

According to some example embodiments, an interconnection via 175 may be placed within the third interlayer insulation film 194. The interconnection via 175 may penetrate the first etching stopping film 193 and be directly connected to the first source/drain contact 171, the second source/drain contact 172, the first gate electrode 120, and the second gate electrode 220. The interconnection via 175 may be placed on the first source/drain contact 171, the second source/drain contact 172, the first gate electrode 120, and the second gate electrode 220.

According to some example embodiments, the interconnection via 175 may include a via barrier film 175a and via filling film 175b. The via barrier film 175a may extend along the sidewalls and the bottom surface of the via filling film 175b. For example, the via barrier film 175a may include at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a 2D material. For example, the via filling film 175b may include at least one of aluminum (Al), tungsten (W), cobalt (Co), ruthenium (Ru), copper (Cu), silver (Ag), gold (Au), manganese (Mn) and molybdenum (Mo).

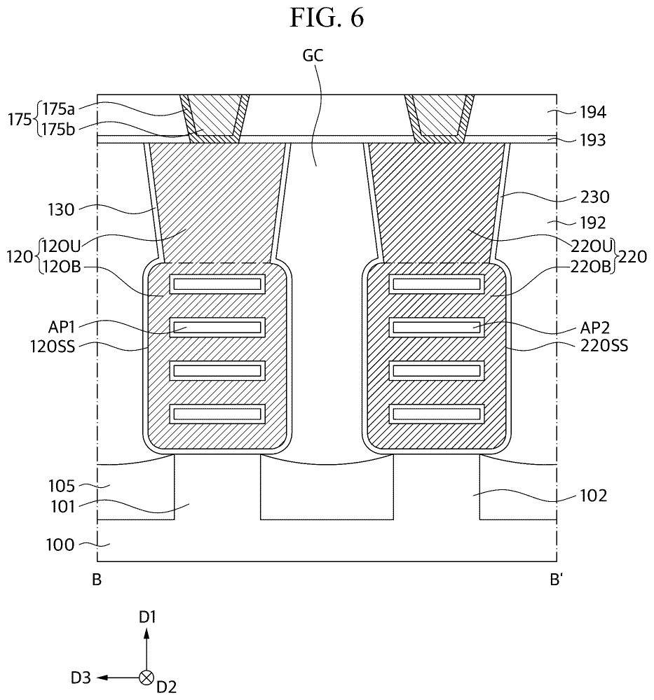

FIG. 6 to FIG. 9 are cross-sectional views taken along line B-B′ of FIG. 1 to illustrate semiconductor devices according to an example embodiment. To facilitate understanding of the present disclosure, differences from those described with reference to FIG. 1 to FIG. 5 will be mainly explained.

Referring to FIG. 6, the first side surface 120SS of the first gate electrode 120 and the second side surface 220SS of the second gate electrode 220 may be parallel in the first direction D1. For example, the first side surface 120SS of the first gate electrode 120 and the second side surface 220SS of the second gate electrode 220 may be aligned with the (100) crystal plane.

According to some example embodiments, the first lower portion pattern 120B may include a region with a constant width in the third direction D3. For example, the first lower portion pattern 120B may include a first bottom region connected to the first fin-shape pattern 101 and having a width that increases in the third direction D3 as the first lower portion pattern 120B gets farther from the first fin-shape pattern 101 in the first direction D1, a first top region that is connected to the first upper portion pattern 120U and has a width that decreases in the third direction D3 as the first lower portion pattern 120B gets farther from the first fin-shape pattern 101 in the first direction D1, and a first middle region placed between first bottom region and first top region. The first middle region of the first lower portion pattern 120B may have a constant width in the third direction D3.

According to some example embodiments, the second lower portion pattern 220B may include a region of constant width in the third direction D3. For example, the second lower portion pattern 220B may include a second bottom region connected to the second fin-shape pattern 102 and having a width that increases in the third direction D3 as the second lower portion pattern 220B gets farther from the second fin-shape pattern 102 in the first direction D1, a second top region connected to the second upper portion pattern 220U and having a width that decreases in the third direction D3 as the second lower portion pattern 220B gets farther from the second fin-shape pattern 102 in the first direction D1, and a second middle region placed between the second bottom region and the second top region. The second middle region of the second lower portion pattern 220B may have a constant width along the third direction D3.

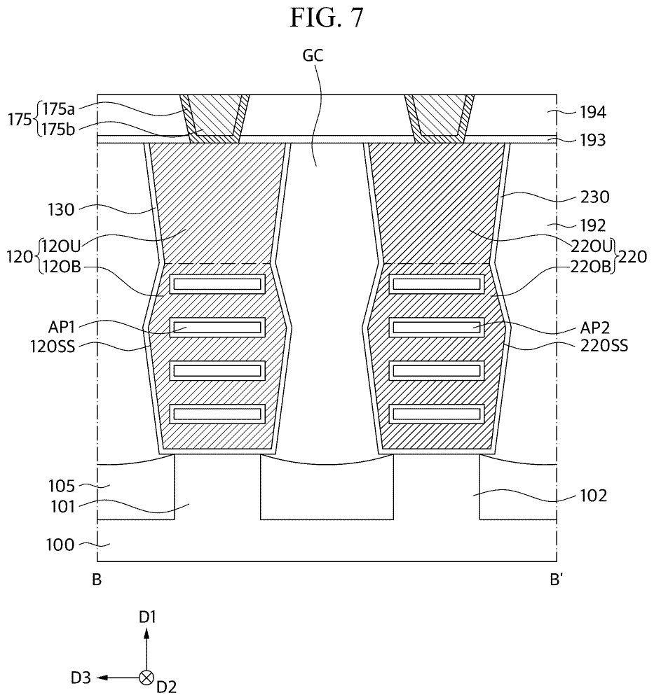

Referring to FIG. 7, the first side surface 120SS of the first gate electrode 120 and the second side surface 220SS of the second gate electrode 220 may not include a surface parallel in the first direction D1. For example, the first side surface 120SS of the first gate electrode 120 and the second side surface 220SS of the second gate electrode 220 may be aligned with the (111) crystal plane. The first side surface 120SS of the first gate electrode 120 and the second side surface 220SS of the second gate electrode 220 may include a plurality of facet surfaces that are not parallel in the first direction D1 and intersect at a desired and/or alternatively desired and/or alternatively predetermined angle.

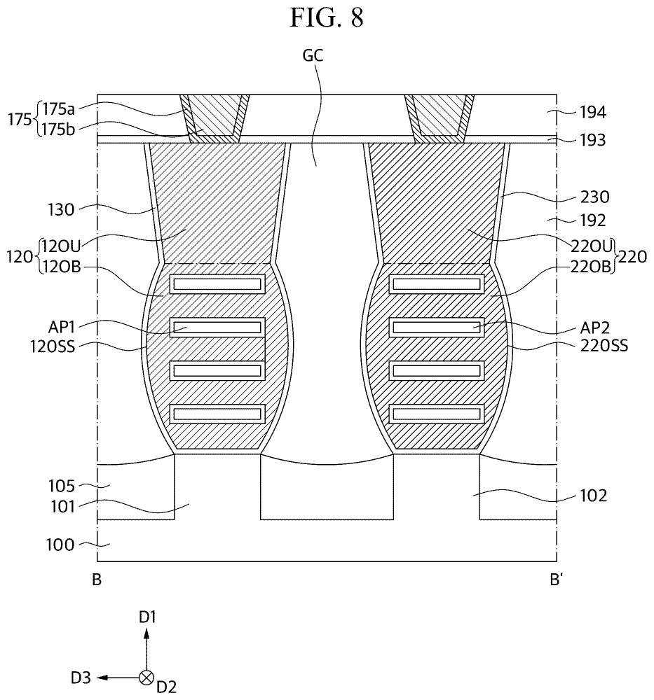

Referring to FIG. 8, the first side surface 120SS of the first gate electrode 120 and the second side surface 220SS of the second gate electrode 220 may have a round shape. The first side surface 120SS of the first gate electrode 120 may be convexly bent outwardly with respect to the center of the first active pattern AP1 in the third direction D3. The second side surface 220SS of the second gate electrode 220 may be convexly bent outwardly with respect to the center of the second active pattern AP2 in the third direction D3. Depending on the process conditions under which the first gate electrode 120 and the second gate electrode 220 are formed, the profiles of the first side surface 120SS of the first gate electrode 120 and the second side surface 220SS of the second gate electrode 220 may change.

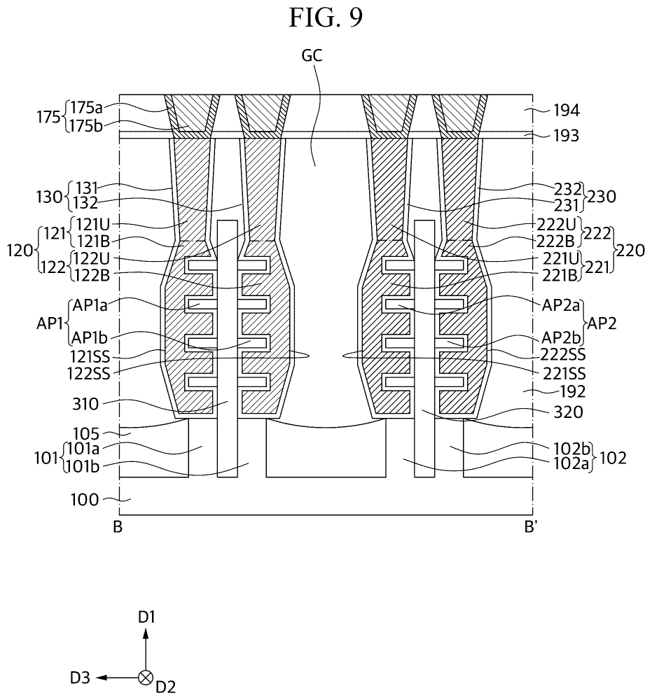

Referring to FIG. 9, the semiconductor device may further include a first insulation column 310 on the first fin-shape pattern 101 and a second insulation column 320 on the second fin-shape pattern 102.

According to some example embodiments, the first insulation column 310 may be extended in the first direction D1 on the first fin-shape pattern 101. The first insulation column 310 may be placed between a first active portion AP1a and a second active portion AP1b. The first insulation column 310 may separate the first active pattern AP1 into the first active portion AP1a and the second active portion AP1b. The first active portion AP1a and the second active portion AP1b spaced apart by the first insulation column 310 may serve as a channel region of a forksheet field effect transistor (forksheet FET). The first insulation column 310 may be inserted into the first fin-shape pattern 101. The first insulation column 310 may separate the first fin-shape pattern 101 into a first fin-shape part 101a and a second fin-shape part 101b. The first active portion AP1a may be placed on the first fin-shape part 101a in the first direction D1. The second active portion AP1b may be placed on the second fin-shape part 101b in the first direction D1.

According to some example embodiments, the first gate electrode 120 may include a first gate part 121 and a second gate part 122. The first gate part 121 and the second gate part 122 may be spaced apart in the third direction D3 with the first insulation column 310 interposed therebetween. The first gate part 121 may be placed on one side of the first insulation column 310, and the second gate part 122 may be placed on the other side of the first insulation column 310. The first gate part 121 may be placed on one side that is opposite to the side of the first insulation column 310 facing the second active pattern AP2 in the third direction D3. The second gate part 122 may be placed on the side of the first insulation column 310 facing the second active pattern AP2 in the third direction D3.

According to some example embodiments, the first gate part 121 may surround the first active portion AP1a. The first gate part 121 may fill the space formed by the first active portion AP1a and the first insulation column 310. For example, the first gate part 121 may be placed between a plurality of first sheets of the first active portion AP1a spaced apart in the first direction D1.

According to some example embodiments, the first gate part 121 may include a first part upper portion pattern 121U and a first part lower portion pattern 121B. The first part upper portion pattern 121U and the first part lower portion pattern 121B may be connected in the first direction D1.

According to some example embodiments, the first part lower portion pattern 121B may be placed lower than the upper surface of the first insulation column 310. The first part lower portion pattern 121B may surround the first active portion AP1a. A first part side surface 121SS of the first part lower portion pattern 121B may include a facet surface. The first part side surface 121SS of the first part lower portion pattern 121B may be a surface that is opposite to the side surface in the third direction of the first part lower portion pattern 121B facing the first insulation column 310. The first part side surface 121SS of the first part lower portion pattern 121B may be convex outward in the third direction D3 based on the first insulation column 310. The width along the third direction D3 of the first part lower portion pattern 121B may increase and then decrease again as the first part lower portion pattern 121B gets farther from the substrate 100 in the first direction D1.

According to some example embodiments, the first part lower portion pattern 121B may include a facet surface that intersects the upper surface of the top first sheet and the first insulation column 310 at a desired and/or alternatively predetermined angle between the top first sheet and the first insulation column 310 that protrudes upward from the top first sheet, which is placed at the top in the first direction D1 among the first active portions AP1a. The first part lower portion pattern 121B may not cover the side surface of the first insulation column 310 that protrudes upwards more than the first active portion AP1a.

According to some example embodiments, the first part upper portion pattern 121U may be placed on the first part lower portion pattern 121B. As the first part upper portion pattern 121U gets farther from the first part lower portion pattern 121B in the first direction D1, the width of the first part upper portion pattern 121U in the third direction D3 may increase.

According to some example embodiments, the second gate part 122 may surround the second active portion AP1b. The second gate part 122 may fill the space formed by the second active portion AP1b and the first insulation column 310. For example, the second gate part 122 may be placed between a plurality of first sheets of the second active portion AP1b spaced apart in the first direction D1.

According to some example embodiments, the second gate part 122 may include a second part upper portion pattern 122U and a second part lower portion pattern 122B. The second part upper portion pattern 122U and the second part lower portion pattern 122B may be placed in the first direction D1.

According to some example embodiments, the second part lower portion pattern 122B may be placed lower than the upper surface of the first insulation column 310. The second part lower portion pattern 122B may surround the second active portion AP1b. A second part side surface 122SS of the second part lower portion pattern 122B may include a facet surface. The second part side surface 122SS of the second part lower portion pattern 122B may be the side surface of the second part lower portion pattern 122B facing the second insulation column 320 in the third direction D3. The second part side surface 122SS of the second part lower portion pattern 122B may be a surface that is placed on the side opposite to the side surface of the second part lower portion pattern 122B in the third direction D3 that faces the first insulation column 310. The second part side surface 122SS of the second part lower portion pattern 122B may be convex outward in a direction opposite to the third direction D3 with respect to the first insulation column 310. The width along the third direction D3 of the second part lower portion pattern 122B may increase and then decrease as the second part lower portion pattern 122B gets farther from the substrate 100 in the first direction D1.

According to some example embodiments, the second part lower portion pattern 122B may include a facet surface that intersects the upper surface of the top first sheet and the first insulation column 310 at a desired and/or alternatively predetermined angle between the top first sheet and the first insulation column 310 that protrudes upward from the top first sheet, which is placed at the top in the first direction D1 among the second active portions AP1b. The second part lower portion pattern 122B may not cover the side surface of the first insulation column 310 that protrudes higher than the second active portion AP1b.

According to some example embodiments, the second part upper portion pattern 122U may be placed on the second part lower portion pattern 122B. As the second part upper portion pattern 122U gets farther from the second part lower portion pattern 122B in the first direction D1, the width of the second part upper portion pattern 122U in the third direction D3 may increase.

According to some example embodiments, based on the first insulation column 310, the first gate part 121 and the second gate part 122 may be placed symmetrically in the third direction D3. For example, each of the first part side surface 121SS of the first gate part 121 and the second part side surface 122SS of the first gate part 121 may include a facet surface having a convex profile in the outward direction relative to the first insulation column 310. The thickness in the third direction D3 of the first gate part 121 placed on the outer side surface of the first active portion AP1a, which is placed on the side opposite to the inner side surface of the first active portion AP1a in contact with the first insulation column 310 may be the same as the thickness in the third direction D3 of the second gate part 122 placed on the outer side surface of the second active portion AP1b, which is placed on the side opposite to the inner side surface of the second active portion AP1b in contact with the first insulation column 310.

According to some example embodiments, the first gate insulation film 130 may include a first part insulation film 131 and a second part insulation film 132. The first part insulation film 131 and the second part insulation film 132 may be spaced apart with the first insulation column 310 interposed therebetween. The first part insulation film 131 and the second part insulation film 132 may not be connected to each other.

According to some example embodiments, the first part insulation film 131 may surround the first gate part 121. The first part insulation film 131 may extend along the surface of the first active portion AP1a and the first insulation column 310. The first part insulation film 131 may cover the lower surface of the first gate part 121, the side surface of the first part upper portion pattern 121U, and the first part side surface 121SS of the first part lower portion pattern 121B. The first part insulation film 131 may not extend along a portion of the first insulation column 310 that protrudes upwards beyond the first active portion AP1a.

According to some example embodiments, the second part insulation film 132 may surround the second gate part 122. The second part insulation film 132 may extend along the surface of the second active portion AP1b and the first insulation column 310. The second part insulation film 132 may cover the lower surface of the second gate part 122, the side surface of the second part upper portion pattern 122U, and the second part side surface 122SS of the second part lower portion pattern 122B. The second part insulation film 132 may not extend along a portion of the first insulation column 310 that protrudes upwards beyond the second active portion AP1b.

According to some example embodiments, the second insulation column 320 may be extended in the first direction D1 on the second fin-shape pattern 102. The second insulation column 320 may be placed between a third active portion AP2a and a fourth active portion AP2b. The second insulation column 320 may separate the second active pattern AP2 into the third active portion AP2a and the fourth active portion AP2b. The third active portion AP2a and the fourth active portion AP2b, which are spaced apart by the second insulation column 320, may serve as a channel region of a forksheet field effect transistor (forksheet FET). The second insulation column 320 may be inserted into the second fin-shape pattern 102. The second insulation column 320 may separate the second fin-shape pattern 102 into a third fin-shape part 102a and a fourth fin-shape part 102b. The third active portion AP2a may be placed on the third fin-shape part 102a in the first direction D1. The fourth active portion AP2b may be placed on the fourth fin-shape part 102b in the first direction D1.

According to some example embodiments, the second gate electrode 220 may include a third gate part 221 and a fourth gate part 222. The third gate part 221 and the fourth gate part 222 may be spaced apart from each other in the third direction D3 with the second insulation column 320 interposed therebetween. The third gate part 221 may be placed on one side of the second insulation column 320, and the fourth gate part 222 may be placed on the other side of the second insulation column 320. The third gate part 221 may be placed on the side of the second insulation column 320 facing the first active pattern AP1 in the third direction D3. The fourth gate part 222 may be placed on the side opposite to the side of the second insulation column 320 facing the first active pattern AP1 in the third direction D3.

According to some example embodiments, the third gate part 221 may surround the third active portion AP2a. The third gate part 221 may fill the space formed by the third active portion AP2a and the second insulation column 320. For example, the third gate part 221 may be placed between a plurality of second sheets of the third active portion AP2a that are spaced apart from each other in the first direction D1.

According to some example embodiments, the third gate part 221 may include a third part upper portion pattern 221U and a third part lower portion pattern 221B. The third part upper portion pattern 221U and the third part lower portion pattern 221B may be connected in the first direction D1.

According to some example embodiments, the third part lower portion pattern 221B may be placed lower than the upper surface of the second insulation column 320. The third part lower portion pattern 221B may surround the third active portion AP2a. A third part side surface 221SS of the third part lower portion pattern 221B may include a facet surface. The third part side surface 221SS of the third part lower portion pattern 221B may be the side surface of the third part lower portion pattern 221B facing the first insulation column 310 in the third direction D3. The third part side surface 221SS of the third part lower portion pattern 221B may be a surface that is placed on the side in the third direction D3 opposite to the side surface of the third part lower portion pattern 221B that faces the second insulation column 320. The third part side surface 221SS of the third part lower portion pattern 221B may be convex outward in the third direction D3 with respect to the second insulation column 320. The width along the third direction D3 of the third part lower portion pattern 221B may increase and then decrease as the third part lower portion pattern 221B gets farther from the substrate 100 in the first direction D1.

According to some example embodiments, the third part lower portion pattern 221B may a facet surface that intersects the upper surface of the top second sheet and the second insulation column 320 at a desired and/or alternatively predetermined angle between the top second sheet and the second insulation column 320 that protrudes upward from the top second sheet, which is placed at the top in the first direction D1 among the third active portions AP2a. The third part lower portion pattern 221B may not cover the side surface of the second insulation column 320 that protrudes upwards more than the third active portion AP2a.

According to some example embodiments, the third part upper portion pattern 221U may be placed on the third part lower portion pattern 221B. As the third part upper portion pattern 221U gets farther from the third part lower portion pattern 221B in the first direction D1, the width of the third part upper portion pattern 221U along the third direction D3 may increase.

According to some example embodiments, the fourth gate part 222 may surround the fourth active portion AP2b. The fourth gate part 222 may fill the space formed by the fourth active portion AP2b and the second insulation column 320. For example, the fourth gate part 222 may be placed between a plurality of second sheets of the fourth active portion AP2b that are spaced apart from each other in the first direction D1.

According to some example embodiments, the fourth gate part 222 may include a fourth part upper portion pattern 222U and a fourth part lower portion pattern 222B. The fourth part upper portion pattern 222U and the fourth part lower portion pattern 222B may be placed in the first direction D1.

According to some example embodiments, the fourth part lower portion pattern 222B may be placed lower than the upper surface of the second insulation column 320. The fourth part lower portion pattern 222B may surround the fourth active portion AP2b. A fourth part side surface 222SS of the fourth part lower portion pattern 222B may include a facet surface. The fourth part side surface 222SS of the fourth part lower portion pattern 222B may be a surface that is placed on the side in the third direction D3 opposite to the side surface of the fourth part lower portion pattern 222B that faces the second insulation column 320. The fourth part side surface 222SS of the fourth part lower portion pattern 222B may be convex outward in a direction opposite to the third direction D3 with respect to the second insulation column 320. The width along the third direction D3 of the fourth part lower portion pattern 222B may increase and then decrease again as the fourth part lower portion pattern 222B gets farther from the substrate 100 in the first direction D1.

According to some example embodiments, the fourth part lower portion pattern 222B may include a facet surface that intersects the upper surface of the top second sheet and the second insulation column 320 at a desired and/or alternatively predetermined angle between the top second sheet and the second insulation column 320 that protrudes upward from the top second sheet, which is placed at the top in the first direction D1 among the fourth active portions AP2b. The fourth part lower portion pattern 222B may not cover the side surface of the second insulation column 320 that protrudes higher than the fourth active portion AP2b.

According to some example embodiments, the fourth part upper portion pattern 222U may be placed on the fourth part lower portion pattern 222B. As the fourth part upper portion pattern 222U gets farther from the fourth part lower portion pattern 222B along the first direction D1, the width of the fourth part upper portion pattern 222U along the third direction D3 may increase.

According to some example embodiments, based on the second insulation column 320, the third gate part 221 and the fourth gate part 222 may be placed symmetrically in the third direction D3. For example, each of the third part side surface 221SS of the third gate part 221 and the fourth part side surface 222SS of the fourth gate part 222 may include a facet surface having a convex profile in the outward direction relative to the second insulation column 320. The thickness in the third direction D3 of the third gate part 221 that is arranged on the outer side surface of the third active portion AP2a, which is arranged on the opposite side to the inner side surface of the third active portion AP2a, which is in contact with the second insulation column 320 may be equal to the thickness in the third direction of the fourth gate part 222 that is arranged on the outer side surface of the fourth active portion AP2b, which is arranged on the opposite side to the inner side surface of the fourth active portion AP2b in contact with the second insulation column 320.

According to some example embodiments, the second gate insulation film 230 may include a third part insulation film 231 and a fourth part insulation film 232. The third part insulation film 231 and the fourth part insulation film 232 may be spaced apart from each other with the second insulation column 320 interposed therebetween. The third part insulation film 231 and the fourth part insulation film 232 may not be connected to each other.

According to some example embodiments, the third part insulation film 231 may surround the third gate part 221. The third part insulation film 231 may extend along the surface of the third active portion AP2a and the second insulation column 320. The third part insulation film 231 may cover the lower surface of the third gate part 221, the side surface of the third part upper portion pattern 221U, and the third part side surface 221SS of the third part lower portion pattern 221B. The third part insulation film 231 may not extend along a portion of the second insulation column 320 that protrudes upwards beyond the third active portion AP2a.

According to some example embodiments, the fourth part insulation film 232 may surround the fourth gate part 222. The fourth part insulation film 232 may extend along the surface of the fourth active portion AP2b and the second insulation column 320. The fourth part insulation film 232 may cover the lower surface of the fourth gate part 222, the side surface of the fourth part upper portion pattern 222U, and the fourth part side surface 222SS of the fourth part lower portion pattern 222B. The fourth part insulation film 232 may not extend along a portion of the second insulation column 320 that protrudes upwards beyond the fourth active portion AP2b.

According to some example embodiments, the first insulation column 310 and the second insulation column 320 may contain insulating material. For example, each of the first insulation column 310 and the second insulation column 320 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and combinations thereof. Even though FIG. 9 illustrates that the first insulation column 310 and the second insulation column 320 include a single film, example embodiments are not limited thereto. For example, it is apparent that the first insulation column 310 and the second insulation column 320 may include multiple films.

FIG. 9 illustrates that the interconnection via 175 is placed on the first gate part 121, the second gate part 122, the third gate part 221, and the fourth gate part 222, respectively, but example embodiments are not limited thereto. For example, at least some of the first gate part 121, the second gate part 122, the third gate part 221 and the fourth gate part 222 may not be connected to the interconnection via 175 and may be connected to the back side vias penetrating the substrate 100 and the first fin-shape pattern 101 or the second fin-shape pattern 102 in the first direction D1.

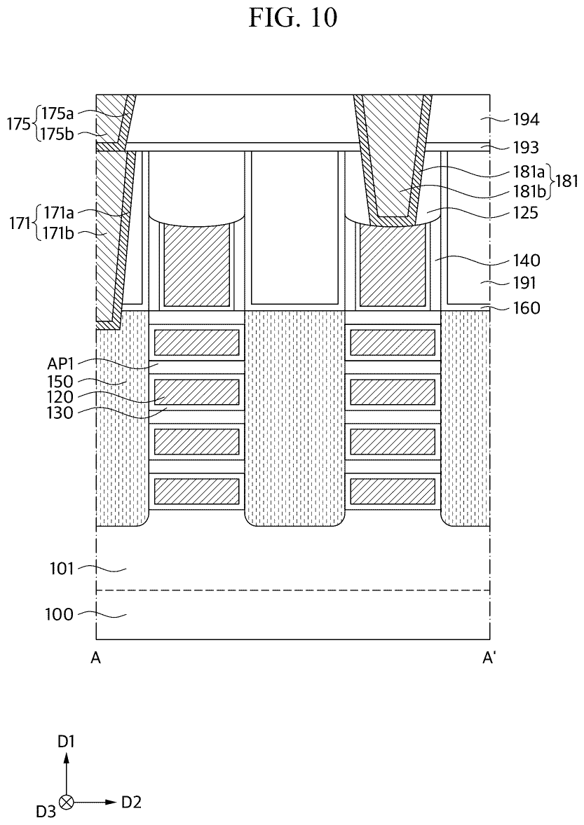

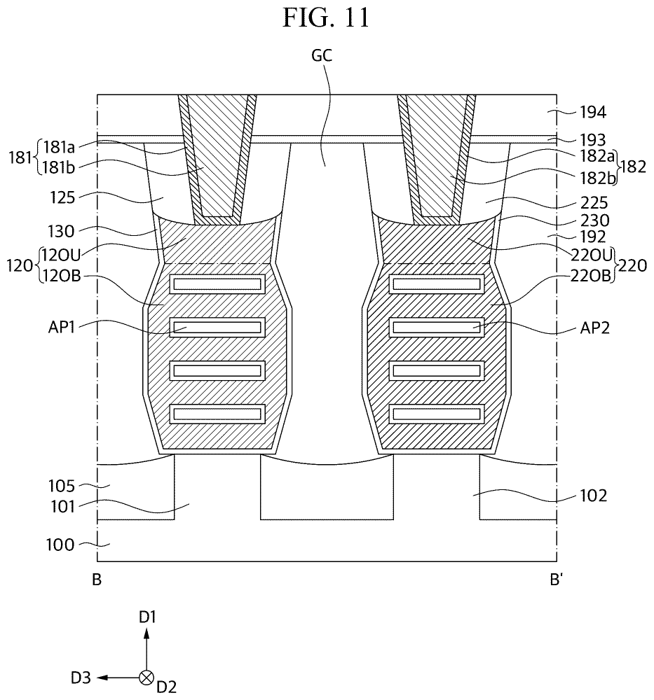

FIG. 10 is a cross-sectional view taken along line A-A′ of FIG. 1 to illustrate a semiconductor device according to an example embodiment. FIG. 11 is a drawing illustrating a cross-section along line B-B′ of FIG. 1 to illustrate a semiconductor device according to an example embodiment. To facilitate understanding of the present disclosure, differences from those described with reference to FIG. 1 to FIG. 5 will be mainly explained.

Referring to FIG. 10 and FIG. 11, the semiconductor device may include a first gate capping film 125, a second gate capping film 225, a first gate contact 181, and a second gate contact 182.

According to some example embodiments, the first gate capping film 125 may be disposed on the first gate electrode 120, the first gate insulation film 130, and the gate spacer 140. The upper surface of the first gate capping film 125 may be placed on the same plane as the upper surface of the first interlayer insulation film 191 and the upper surface of the second interlayer insulation film 192. Unlike what is illustrated, the first gate capping film 125 may be placed between the gate spacers 140 in the second direction D2. In this case, the upper surface of the first gate capping film 125 and the upper surface of the gate spacer 140 may be placed on the same plane.

According to some example embodiments, the first gate capping film 125 may be placed on the first upper portion pattern 120U. The side surface of the first gate capping film 125 in the third direction D3 may be placed on the same plane as the side surface of the first upper portion pattern 120U in the third direction D3. The width of the first gate capping film 125 in the third direction D3 may increase as the first gate capping film 125 gets farther from the first upper portion pattern 120U along the first direction D1.

According to some example embodiments, the second gate capping film 225 may be disposed on the second gate electrode 220, the second gate insulation film 230, and the gate spacer 140. The upper surface of the second gate capping film 225 may be placed on the same plane as the upper surface of the first interlayer insulation film 191 and the upper surface of the second interlayer insulation film 192.

According to some example embodiments, the second gate capping film 225 may be placed on the second upper portion pattern 220U. The side surface of the second gate capping film 225 along the third direction D3 may be placed on the same plane as the side surface of the second upper portion pattern 220U in the third direction D3. The width of the second gate capping film 225 in the third direction D3 may increase as the second gate capping film 225 gets farther from the second upper portion pattern 220U in the first direction D1.

According to some example embodiments, the first gate capping film 125 and the second gate capping film 225 may be surrounded by the second interlayer insulation film 192 in the third direction D3. The side surface along the third direction D3 of the first gate capping film 125 and the side surface in the third direction D3 of the second gate capping film 225 may be covered by the second interlayer insulation film 192. The first gate capping film 125 and the second gate capping film 225 may penetrate at least a portion of the second interlayer insulation film 192 in the first direction D1. The upper surface of the first gate capping film 125 and the upper surface of the second gate capping film 225 may be placed on the same plane as the upper surface of the gate separation structure GC and the upper surface of the second interlayer insulation film 192.

According to some example embodiments, the first gate capping film 125 and the second gate capping film 225 may include, for example, at least one of silicon nitride (SiN), silicon oxide (SiO₂), silicon oxynitride (SiON), silicon carbonitride (SiCN), silicon oxycarbonitride (SiOCN), and combinations thereof. The first gate capping film 125 and the second gate capping film 225 may include materials having etch selectivity with respect to the first interlayer insulation film 191 and the second interlayer insulation film 192.

According to some example embodiments, the first gate contact 181 may be placed on the first gate electrode 120. The first gate contact 181 may be connected to the first gate electrode 120 by penetrating the first gate capping film 125, the first etching stopping film 193, and the third interlayer insulation film 194.

According to some example embodiments, the first gate contact 181 may include a first gate contact barrier film 181a, and a first gate contact filling film 181b surrounded by the first gate contact barrier film 181a. Description on the material contained in the first gate contact barrier film 181a and the first gate contact filling film 181b may be identical to the description for the material contained in the first source/drain contact barrier film 171a and the first source/drain contact filling film 171b.

According to some example embodiments, the second gate contact 182 may be placed on the second gate electrode 220. The second gate contact 182 may be connected to the second gate electrode 220 by penetrating the second gate capping film 225, the first etching stopping film 193, and the third interlayer insulation film 194.

According to some example embodiments, the second gate contact 182 may include a second gate contact barrier film 182a and a second gate contact filling film 182b on the second gate contact barrier film 182a. Description on the material contained in the second gate contact barrier film 182a and the second gate contact filling film 182b may be identical to the description for the material contained in the first source/drain contact barrier film 171a and the first source/drain contact filling film 171b.

FIG. 10 and FIG. 11 illustrate that the upper surface of the first gate contact 181 and the upper surface of the second gate contact 182 are positioned above the upper surface of the first gate capping film 125 and the upper surface of the second gate capping film 225, but example embodiments are not limited thereto. For example, the upper surface of the first gate contact 181 and the upper surface of the second gate contact 182 may be placed on the same plane as the upper surface of the first gate capping film 125 and the upper surface of the second gate capping film 225. In such a case, the interconnection via 175 may be connected on the first gate contact 181 and the second gate contact 182.

FIG. 10 illustrates that the upper surface of the interconnection via 175 and the upper surface of the first gate contact 181 are placed on the same plane, but example embodiments are not limited thereto. For example, the upper surface of the first gate contact 181 may be placed under the upper surface of the interconnection via 175.

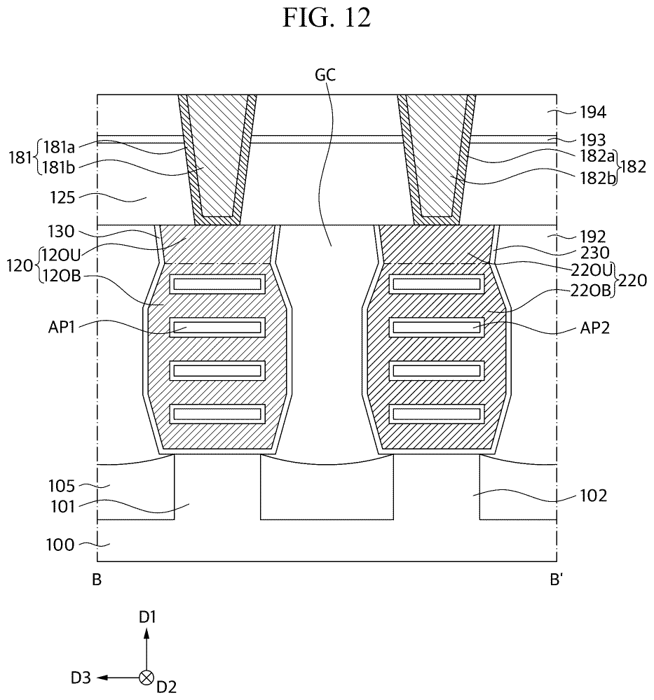

FIG. 12 is a cross-sectional view taken along line B-B′ of FIG. 1 to illustrate a semiconductor device according to an example embodiment. To facilitate understanding of the present disclosure, the following description focuses on differences from those described with reference to FIG. 10 and FIG. 11.

Referring to FIG. 12, the first gate capping film 125 may be disposed on the first gate electrode 120, the second gate electrode 220, the gate separation structure GC, and the second interlayer insulation film 192. The first gate capping film 125 may cover the upper surface of the gate separation structure GC, the upper surface of the first gate electrode 120, and the upper surface of the second gate electrode 220. The first gate capping film 125 may be extended along the third direction D3. The first gate capping film 125 may be disposed on the first upper portion pattern 120U of the first gate electrode 120 and the second upper portion pattern 220U of the second gate electrode 220.

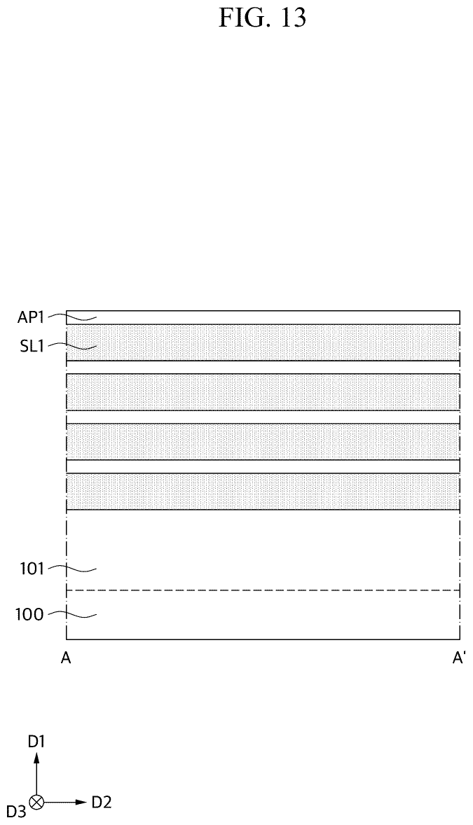

FIG. 13 to FIG. 34 are drawings illustrating intermediate operations for explaining a method of manufacturing the semiconductor device illustrated in FIG. 2 and FIG. 3, according to an example embodiment.

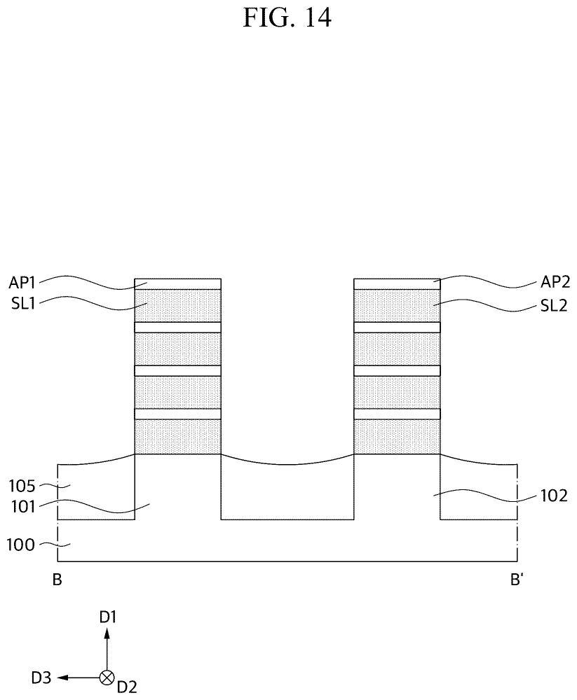

Referring to FIG. 13 and FIG. 14, a first sacrificial film SL1 and the first active pattern AP1 may be alternately laminated and formed on the substrate 100 and the first fin-shape pattern 101. A second sacrificial film SL2 and the second active pattern AP2 may be alternately laminated and formed on the substrate 100 and the second fin-shape pattern 102. The device isolation film 105 may be formed between the first fin-shape pattern 101 and the second fin-shape pattern 102.

According to some example embodiments, the alternately laminated first sacrificial film SL1 and the first active pattern AP1 may be extended along the second direction D2. The alternately laminated second sacrificial film SL2 and the second active pattern AP2 may be extended along the second direction D2. While the first sacrificial film SL1 and the first active pattern AP1 and the second sacrificial film SL2 and the second active pattern AP2 being patterned to be spaced apart in the third direction D3, the first fin-shape pattern 101 and the second fin-shape pattern 102 may be formed on the substrate 100.

According to some example embodiments, the first sacrificial film SL1 and the second sacrificial film SL2 may contain the same material. The first sacrificial film SL1 and the second sacrificial film SL2 may contain different materials from the first active pattern AP1 and the second active pattern AP2. For example, each of the first sacrificial film SL1 and the second sacrificial film SL2 may include silicon germanium (SiGe), and each of the first active pattern AP1 and the second active pattern AP2 may contain silicon (Si).

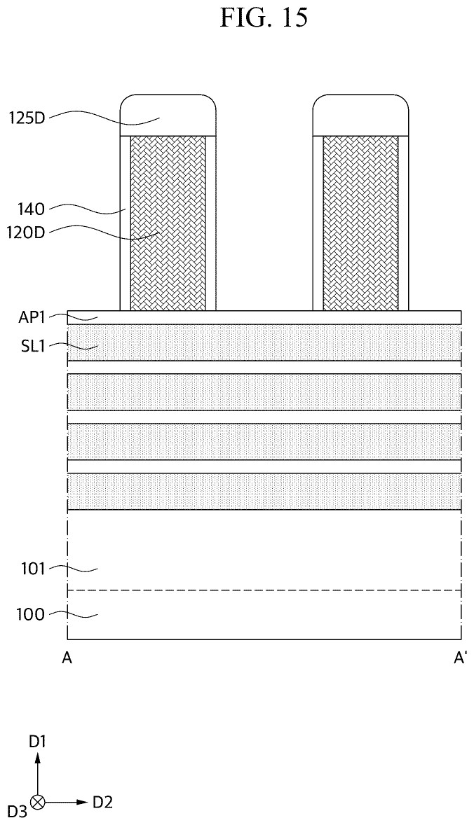

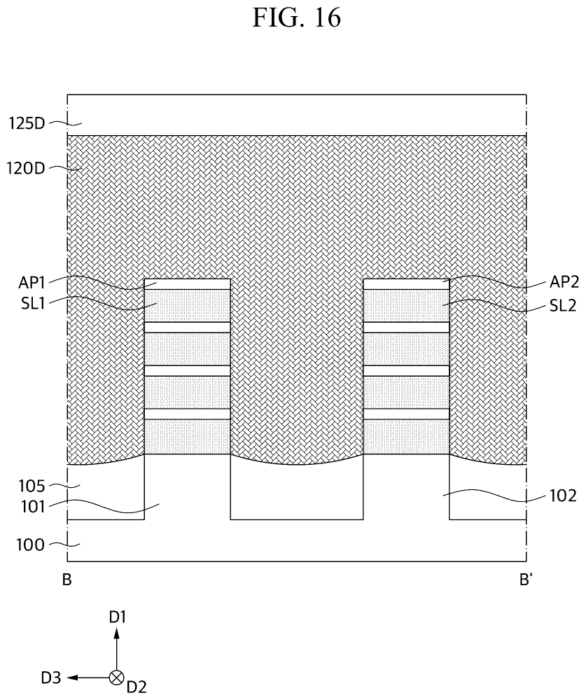

Referring to FIG. 15 and FIG. 16, a dummy gate 120D, the gate spacer 140, and a dummy capping film 125D may be formed.

According to some example embodiments, the dummy gate 120D may be formed on the alternately laminated first sacrificial film SL1 and the first active pattern AP1 and the alternately laminated second sacrificial film SL2 and the second active pattern AP2. The dummy gate 120D may be extended to the third direction D3. The dummy gate 120D may be formed on the device isolation film 105. The dummy gate 120D may be placed between a pair of gate spacers 140 in the second direction D2. The dummy gate 120D may be placed in multiple places spaced apart in the second direction D2.

According to some example embodiments, the dummy capping film 125D may be placed on the dummy gate 120D and the gate spacer 140. The dummy capping film 125D may cover the dummy gate 120D and the gate spacer 140. The dummy gate 120D may contain, for example, polysilicon, and the dummy capping film 125D may contain, for example, silicon nitride. However, example embodiments are not limited thereto.

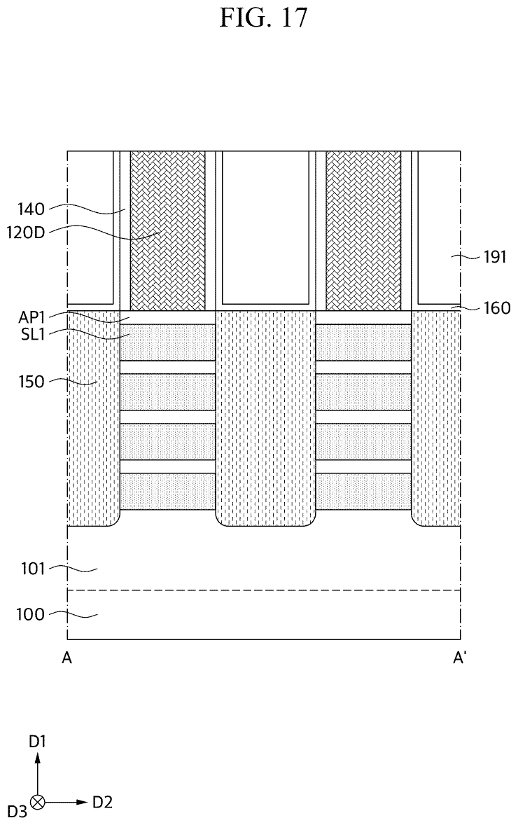

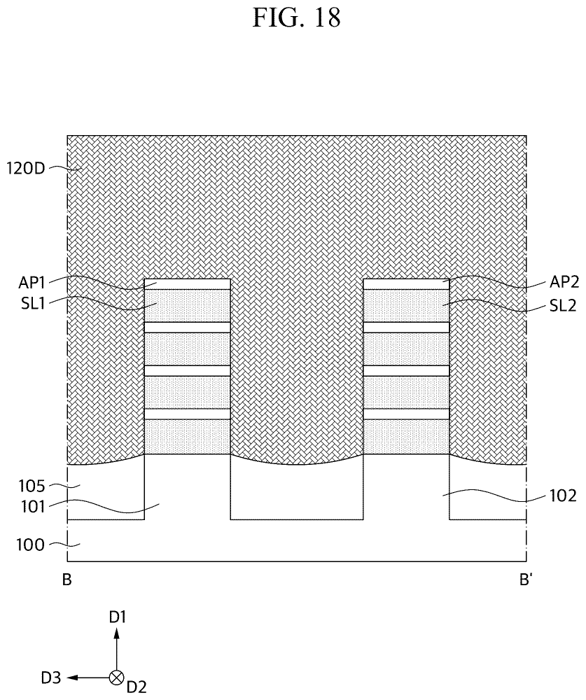

Referring to FIG. 17 and FIG. 18, the first sacrificial film SL1 and the first active pattern AP1, which are alternately stacked using the dummy gate 120D, the gate spacer 140, and the dummy capping film 125D (in FIG. 15), may be patterned in the second direction D2, and the first source/drain pattern 150 may be formed. After then, the source/drain etching stopping film 160 and the first interlayer insulation film 191 may be formed on the first source/drain pattern 150 and the second source/drain pattern 250 (of FIG. 5). In the process of forming the first source/drain pattern 150, the second source/drain pattern 250 (in FIG. 5), the source/drain etching stopping film 160, and the first interlayer insulation film 191, the dummy capping film 125D (in FIG. 15) may be removed.

According to some example embodiments, in order for the first sacrificial film SL1 and the first active pattern AP1 extending along the second direction D2 to be spaced apart in the second direction D2, a portion of the first sacrificial film SL1 and the first active pattern AP1 may be removed and patterned using the dummy gate 120D, the gate spacer 140, and the dummy capping film 125D (in FIG. 15). For example, the first sacrificial film SL1 and the first active pattern AP1 may be patterned through an etching process using the dummy gate 120D, the gate spacer 140, and the dummy capping film 125D (in FIG. 15) as a mask. After then, the first source/drain pattern 150 may be formed between the first sacrificial film SL1 and the first active pattern AP1 spaced apart in the second direction D2. For example, the first source/drain pattern 150 may be formed by epitaxial growth from the first sacrificial film SL1.

According to some example embodiments, in order for the second sacrificial film SL2 and the second active pattern AP2 extending along the second direction D2 to be spaced apart in the second direction D2, a portion of the second sacrificial film SL2 and the second active pattern AP2 may be removed and patterned using the dummy gate 120D, the gate spacer 140, and the dummy capping film 125D (in FIG. 15). For example, the second sacrificial film SL2 and the second active pattern AP2 may be patterned through an etching process using the dummy gate 120D, the gate spacer 140, and the dummy capping film 125D (in FIG. 15) as masks. After then, the second source/drain pattern 250 (in FIG. 5) may be formed between the second sacrificial film SL2 and the second active pattern AP2 spaced in the second direction D2. The second source/drain pattern 250 (in FIG. 5) may be formed, for example, by epitaxial growth from the second sacrificial film SL2.

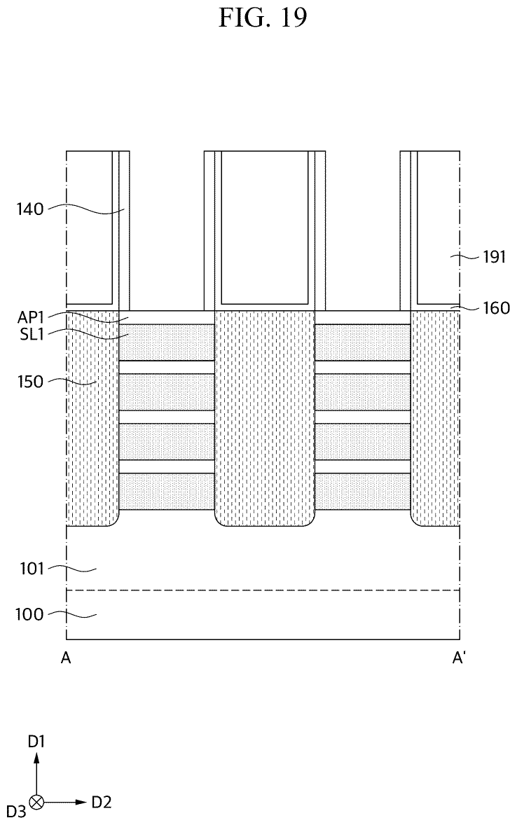

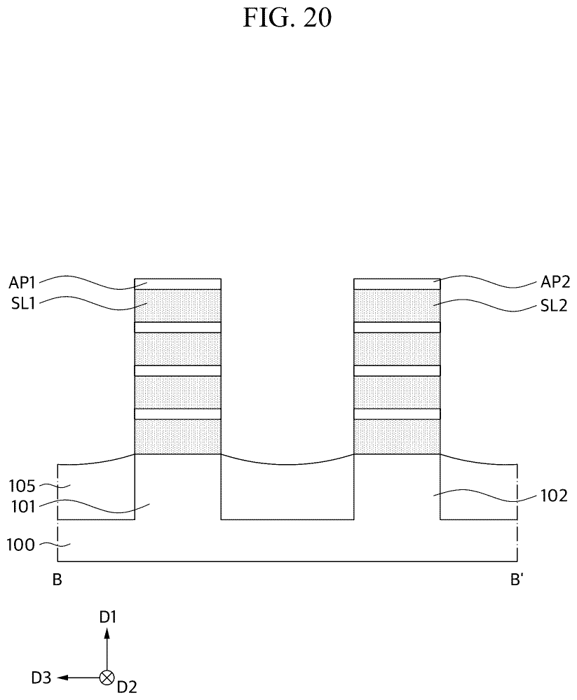

Referring to FIG. 19 and FIG. 20, the dummy gate 120D (in FIG. 17 and FIG. 18) may be removed. For example, the dummy gate 120D (in FIG. 17 and FIG. 18) may be removed through an etching process. The first active pattern AP1 may be exposed between the gate spacers 140 in the second direction D2. The device isolation film 105 may be exposed between the alternately laminated first sacrificial film SL1 and the first active pattern AP1 and the alternately laminated second sacrificial film SL2 and the second active pattern AP2.

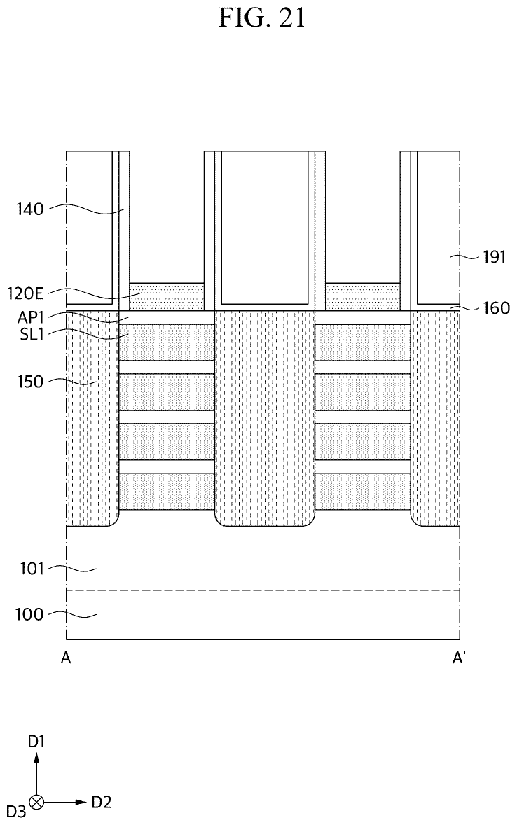

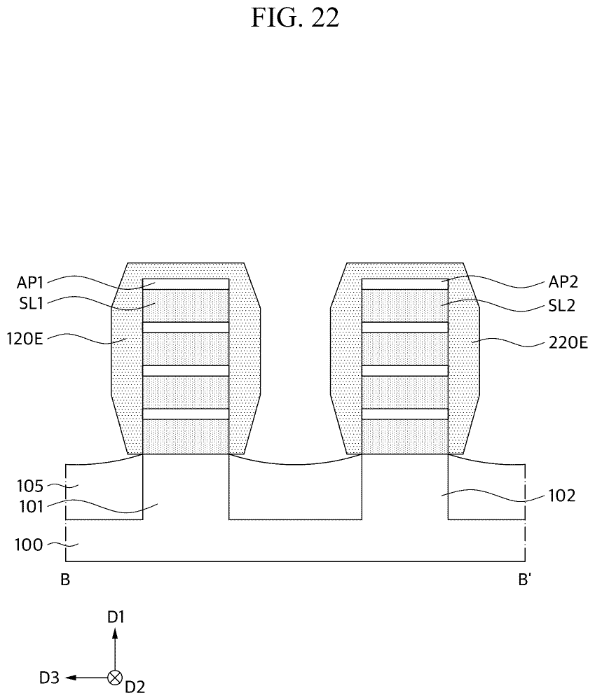

Referring to FIG. 21 and FIG. 22, a first epitaxial pattern 120E and a second epitaxial pattern 220E may be formed. The first epitaxial pattern 120E and the second epitaxial pattern 220E may be formed between the gate spacers 140 in the second direction D2.

According to some example embodiments, the first epitaxial pattern 120E may be formed by epitaxial growth from the first sacrificial film SL1. The first epitaxial pattern 120E may surround the first sacrificial film SL1 and the first active pattern AP1, which are alternately laminated. The second epitaxial pattern 220E may be formed by epitaxial growth from the second sacrificial film SL2. The second epitaxial pattern 220E may surround the alternately laminated second sacrificial film SL2 and the second active pattern AP2.

According to some example embodiments, the first epitaxial pattern 120E and the second epitaxial pattern 220E may have crystal planes corresponding to the crystal planes of the substrate 100. For example, when the upper surface of the substrate 100 has a (110) crystal plane and the notch of the substrate 100 has a [100] crystal direction, the first epitaxial pattern 120E and the second epitaxial pattern 220E may have (100) crystal plane and (111) crystal plane. In another example embodiment, when the upper surface of the substrate 100 has a (100) crystal plane and the notch of the substrate 100 has a [110] crystal direction, the first epitaxial pattern 120E and the second epitaxial pattern 220E may have (111) crystal plane. In another example embodiment, when the upper surface of the substrate 100 has a (100) crystal plane and the notch of the substrate 100 has a [100] crystal direction, the first epitaxial pattern 120E and the second epitaxial pattern 220E may have (100) crystal plane.

According to some example embodiments, the (100) crystal planes of the first epitaxial pattern 120E and the second epitaxial pattern 220E may be parallel in the first direction D1. The (111) crystal planes of the first epitaxial pattern 120E and the second epitaxial pattern 220E intersect the first direction D1 and the third direction D3, and may be tilted with respect to the first direction D1.

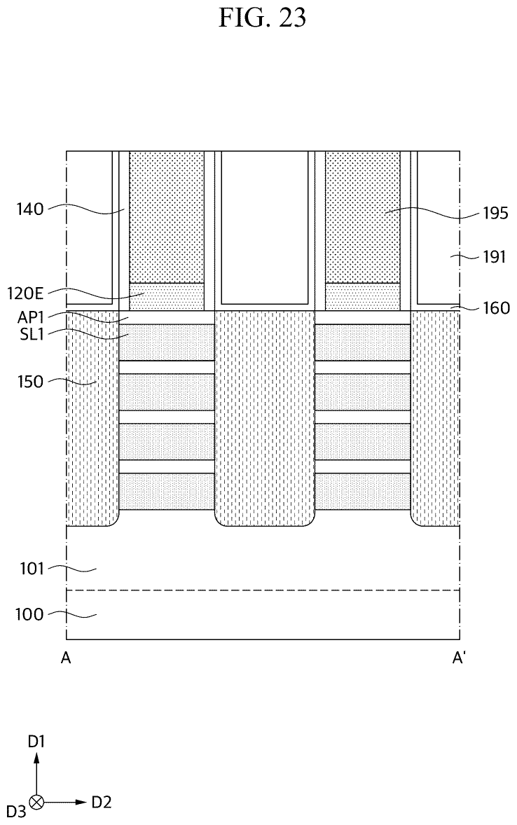

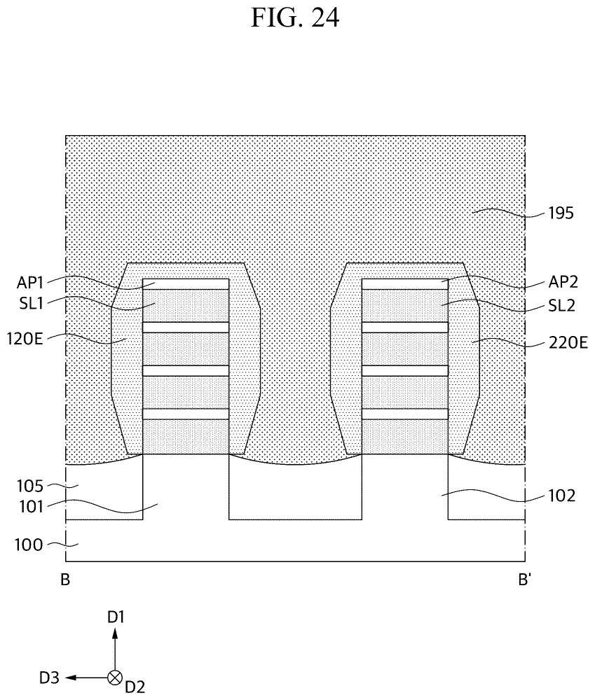

Referring to FIG. 23 and FIG. 24, a protection film 195 may be formed. The protection film 195 may be formed on the first epitaxial pattern 120E and the second epitaxial pattern 220E. For example, the protection film 195 may contain carbon-based materials. The protection film 195 may include at least one of a photoresist film, an amorphous carbon layer (ACL), a spin on hardmask (SOH), a spin on carbon (SOC), and a silicon nitride film.

According to some example embodiments, the protection film 195 may be placed between the gate spacers 140 in the second direction D2. The protection film 195 may extend along the third direction D3 between the gate spacers 140. The protection film 195 may cover the device isolation film 105.

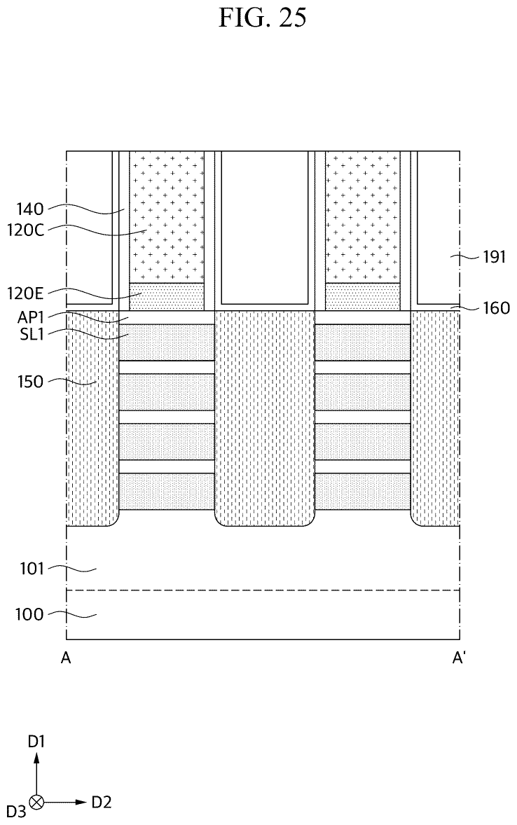

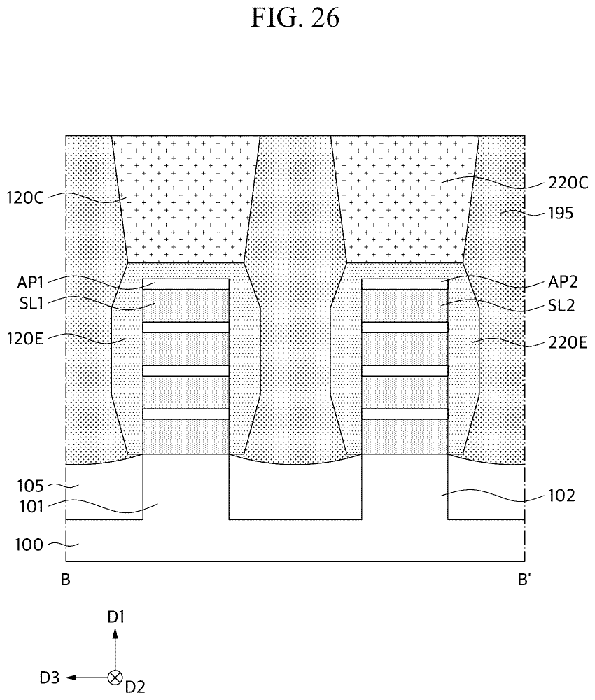

Referring to FIG. 25 and FIG. 26, a first contact pattern 120C and a second contact pattern of 220C may be formed. The first contact pattern 120C may be formed on the first epitaxial pattern 120E by penetrating a portion of the protection film 195. The second contact pattern 220C may be formed on the second epitaxial pattern 220E by penetrating a portion of the protection film 195.

According to some example embodiments, a portion of the protection film 195 may be removed to form a trench exposing the first epitaxial pattern 120E and the second epitaxial pattern 220E. For example, the portion of the protection film 195 may be removed through the etching process to form a trench. The first contact pattern 120C and the second contact pattern 220C may be formed within the formed trench. The first contact pattern 120C and the second contact pattern 220C may include, for example, at least one of silicon oxide, silicon nitride, silicon oxynitride and low-k material.

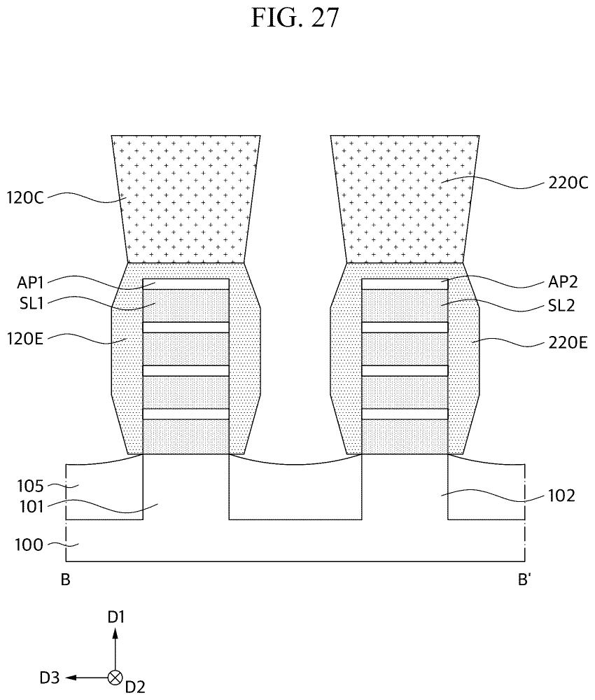

Referring to FIG. 27, the protection film (195 of FIG. 26) may be removed. As the protection film 195 (of FIG. 26) is removed, the first epitaxial pattern 120E and the first contact pattern 120C, the second epitaxial pattern 220E and the second contact pattern 220C, and the device isolation film 105 may be exposed.

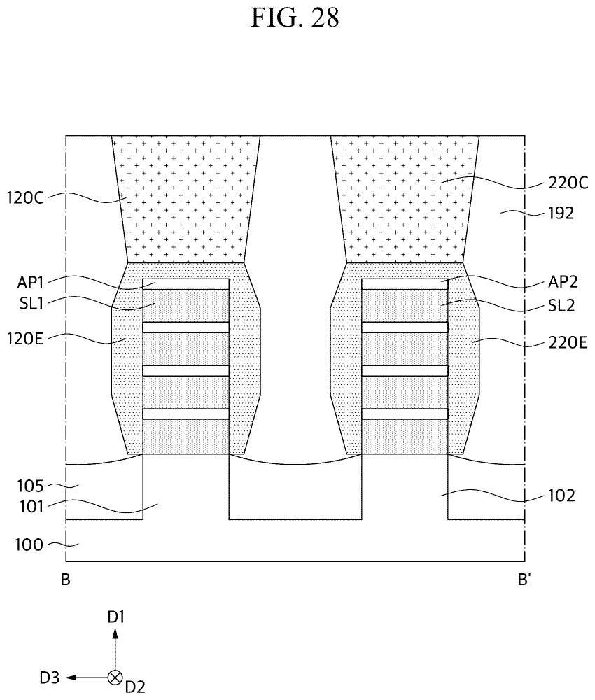

Referring to FIG. 28, the second interlayer insulation film 192 may be formed. The second interlayer insulation film 192 may be formed on the first epitaxial pattern 120E and the first contact pattern 120C, the second epitaxial pattern 220E and the second contact pattern 220C, and the device isolation film 105. The second interlayer insulation film 192 may surround the first epitaxial pattern 120E and the first contact pattern 120C, and the second epitaxial pattern 220E and the second contact pattern 220C.

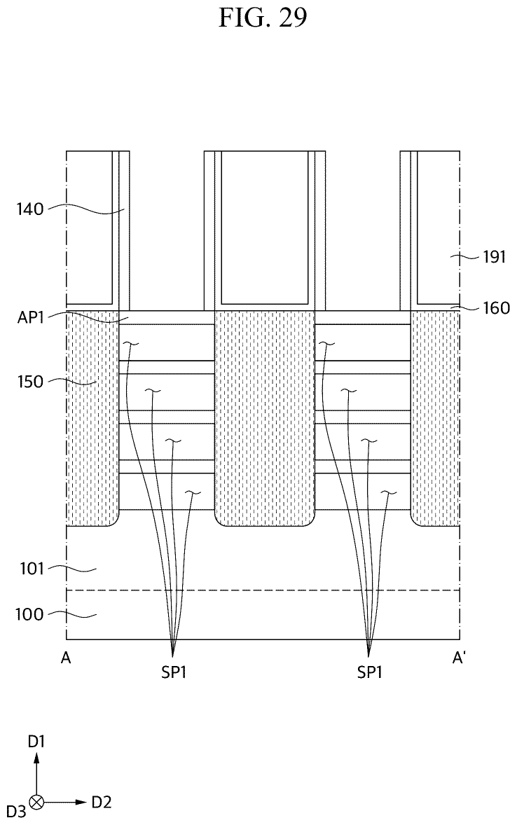

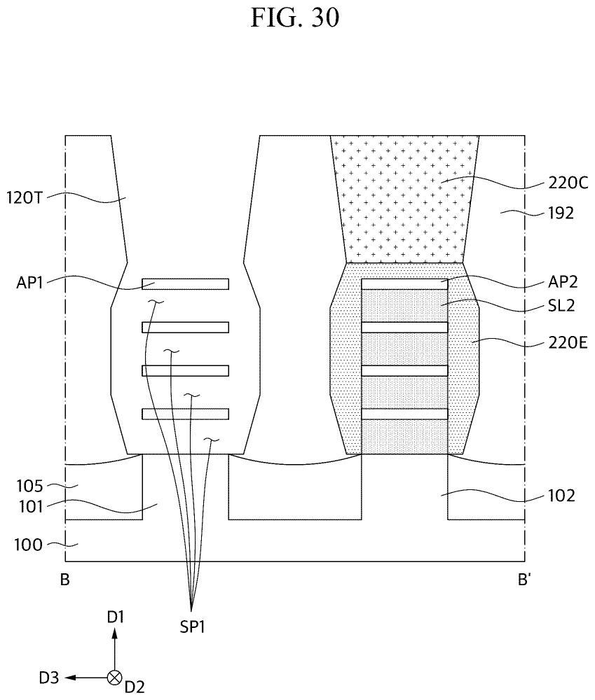

Referring to FIG. 29 and FIG. 30, the first sacrificial film SL1 (in FIG. 25 and FIG. 28), the first epitaxial pattern 120E (in FIG. 25 and FIG. 28) and the first contact pattern 120C (in FIG. 25 and FIG. 28) may be removed. As the first sacrificial film SL1 (in FIG. 25 and FIG. 28) is removed, a first space SP1 may be formed between the first active pattern AP1 in the first direction D1. The first epitaxial pattern 120E (in FIG. 25 and FIG. 28) and the first contact pattern 120C (in FIG. 25 and FIG. 28) may be removed to form a first gate electrode trench 120T within the second interlayer insulation film 192.

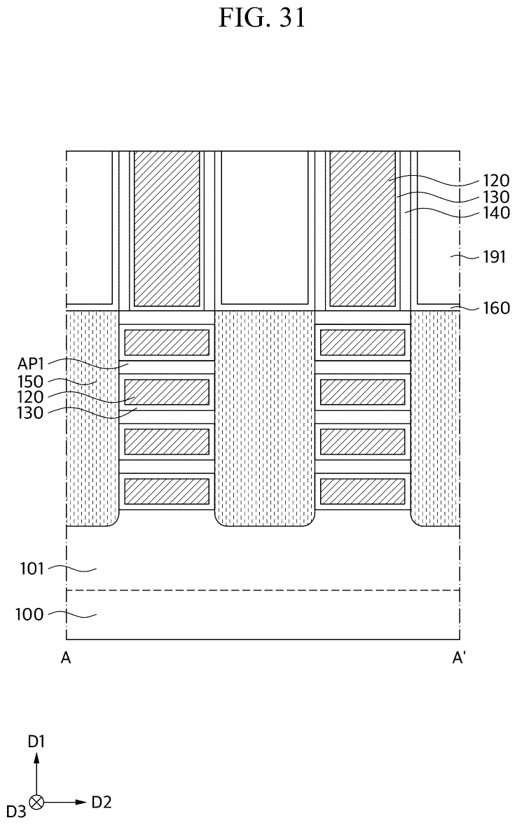

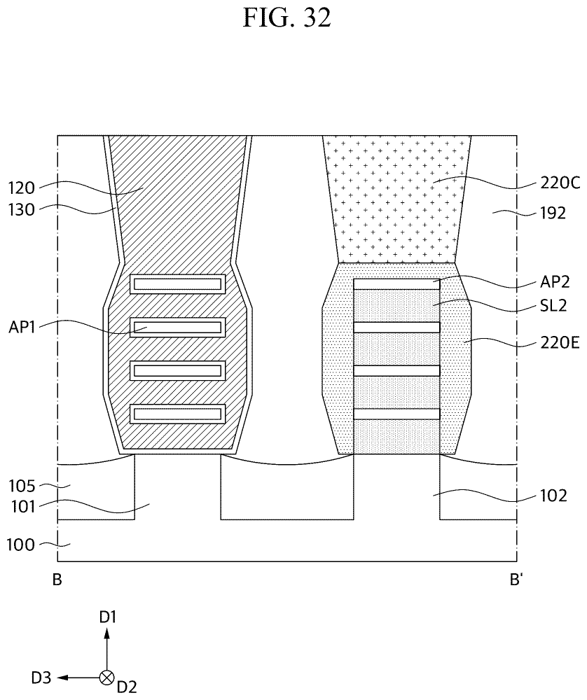

Referring to FIG. 31 and FIG. 32, the first gate insulation film 130 and the first gate electrode 120 may be formed. The first gate insulation film 130 and the first gate electrode 120 may be formed in the first space SP1 (of FIG. 29 and FIG. 30). The first gate insulation film 130 may surround the first active pattern AP1. The first gate insulation film 130 may extend along the bottom and side surfaces of the first gate electrode trench 120T (in FIG. 30). The first gate electrode 120 may fill the first gate electrode trench 120T (in FIG. 30) on the first gate insulation film 130.

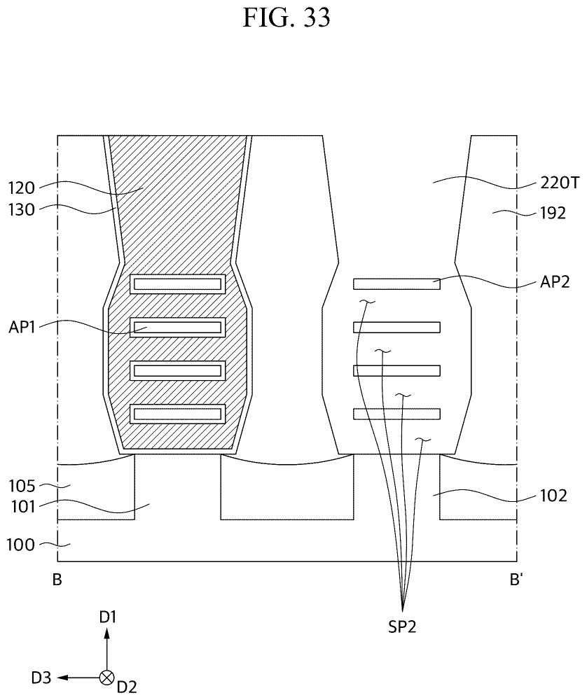

Referring to FIG. 33, the second sacrificial film SL2 (in FIG. 32), the second epitaxial pattern 220E (in FIG. 32) and the second contact pattern 220C (in FIG. 32) may be removed. As the second sacrificial film SL2 (in FIG. 32) is removed, a second space SP2 may be formed between the second active pattern AP2 in the first direction D1. A second gate electrode trench 220T may be formed within the second interlayer insulation film 192 when the second epitaxial pattern 220E (in FIG. 32) and the second contact pattern 220C (in FIG. 32) are removed.

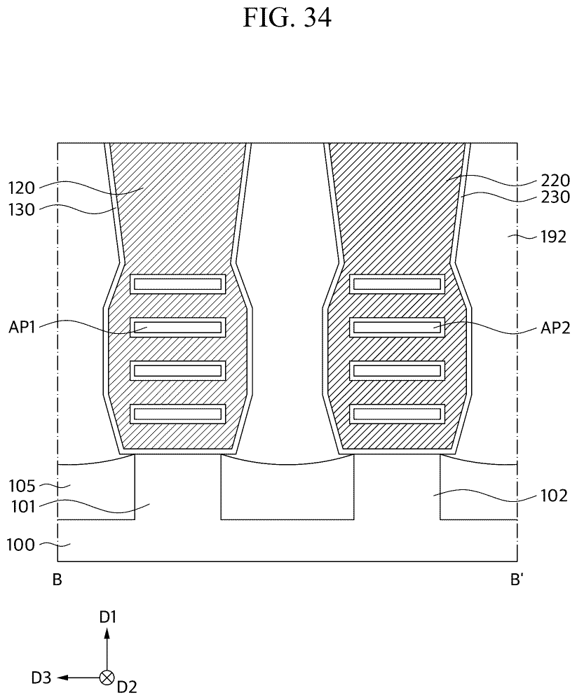

Referring to FIG. 34, the second gate insulation film 230 and the second gate electrode 220 may be formed. The second gate insulation film 230 and the second gate electrode 220 may be formed in the second space SP2 (of FIG. 33). The second gate insulation film 230 may surround the second active pattern AP2. The second gate insulation film 230 may extend along the bottom and side surfaces of the second gate electrode trench 220T (of FIG. 33). The second gate electrode 220 may fill the second gate electrode trench 220T (of FIG. 33) on the second gate insulation film 230.

After then, referring to FIG. 2 and FIG. 3, the first etching stopping film 193 and the third interlayer insulation film 194 may be formed on the second interlayer insulation film 192, and the first source/drain contact 171 and the second source/drain contact 172, and the interconnection via 175 may be formed.

According to some example embodiments, when a semiconductor device is manufactured according to a method of manufacturing a semiconductor device of the present disclosure, the first epitaxial pattern 120E (of FIG. 24) and the second epitaxial pattern 220E (of FIG. 24) may be replaced with the first gate electrode 120 (of FIG. 34) and the second gate electrode 220 (of FIG. 34). Therefore, without a separate process of forming the gate separation structure GC (of FIG. 3) between the first gate electrode 120 (of FIG. 34) and the second gate electrode 220 (of FIG. 34), in the process of forming the first epitaxial pattern 120E (of FIG. 24) and the second epitaxial pattern 220E (of FIG. 24) and replacing them with the first gate electrode 120 (of FIG. 34) and the second gate electrode 220 (of FIG. 34), the first gate electrode 120 (of FIG. 34) and the second gate electrode 220 (of FIG. 34) may be spaced apart and electrically insulated.

According to some example embodiments, while the difficulty of the process of forming the gate separation structure GC (of FIG. 3) between the first gate electrode 120 (of FIG. 34) and the second gate electrode 220 (of FIG. 34) becomes more difficult as the semiconductor devices are downscaled, the gap between the first gate electrode 120 (of FIG. 34) and the second gate electrode 220 (of FIG. 34) becomes narrower, the semiconductor device of the present disclosure may stably form the gate separation structure GC (of FIG. 3) by replacing the first epitaxial pattern 120E (of FIG. 24) and the second epitaxial pattern 220E (of FIG. 24) with the first gate electrode 120 (of FIG. 34) and the second gate electrode 220 (of FIG. 34), without a separate process for forming the gate separation structure GC (of FIG. 3). According to example embodiments, it is possible to reduce the difficulty of the manufacturing process of semiconductor devices.

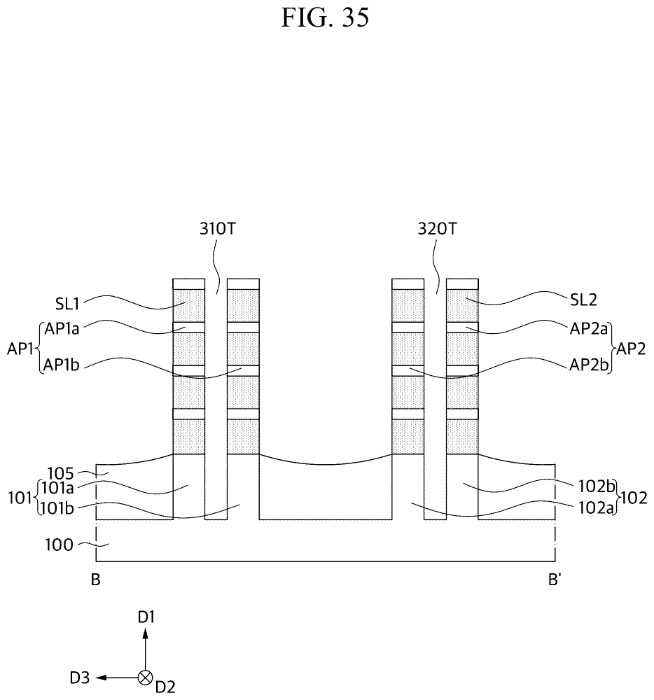

FIG. 35 to FIG. 45 are drawings illustrating intermediate operations for explaining a method for manufacturing a semiconductor device illustrated in FIG. 9, according to an example embodiment. To facilitate understanding of the present disclosure, the following description focuses on differences from those described with reference to FIG. 13 to FIG. 34. FIG. 35 is a drawing illustrating the operations after FIG. 14.

Referring to FIG. 14 and FIG. 35, a first insulation column trench 310T may be formed on the first fin-shape pattern 101, and a second insulation column trench 320T may be formed on the second fin-shape pattern 102.

According to some example embodiments, a portion of the alternately laminated first sacrificial film SL1 and the first active pattern AP1 may be removed to form the first insulation column trench 310T. As the first insulation column trench 310T is formed, the first active pattern AP1 may be separated into the first active portion AP1a and the second active portion AP1b.

According to some example embodiments, a portion of the alternately laminated second sacrificial film SL2 and the second active pattern AP2 may be removed to form a second insulation column trench 320T. As the second insulation column trench 320T is formed, the second active pattern AP2 may be separated into the third active portion AP2a and the fourth active portion AP2b.

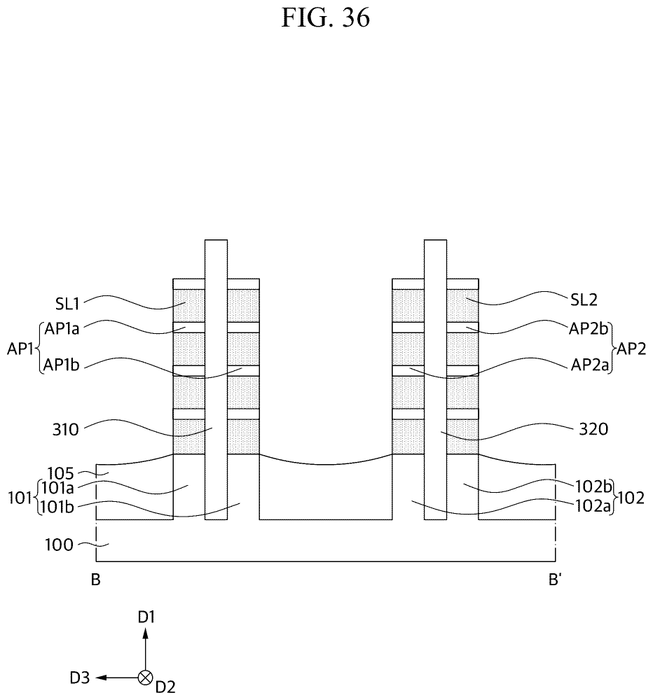

Referring to FIG. 36, the first insulation column 310 and the second insulation column 320 may be formed. Each of the first insulation column 310 and the second insulation column 320 may fill the first insulation column trench 310T (in FIG. 35) and the second insulation column trench 320T (in FIG. 35). The first insulation column 310 may be formed between the first active portion AP1a and the second active portion AP1b. The second insulation column 320 may be formed between the third active portion AP2a and the fourth active portion AP2b. The first insulation column 310 and the second insulation column 320 may be formed to protrude above the first active pattern AP1 and the second active pattern AP2.

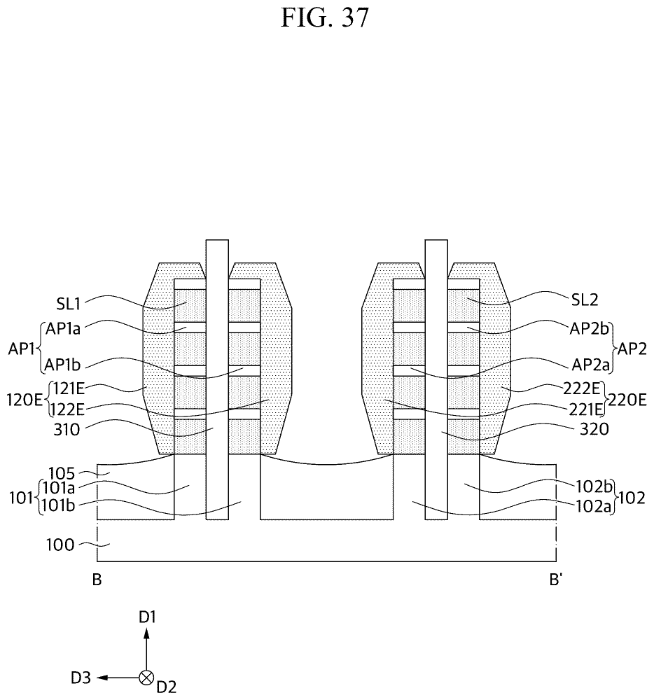

Referring to FIG. 37, the first epitaxial pattern 120E and the second epitaxial pattern 220E may be formed. The first epitaxial pattern 120E may be formed by epitaxial growth from the first sacrificial film SL1. The first epitaxial pattern 120E may surround the first sacrificial film SL1 and the first active pattern AP1, which are alternately laminated. The second epitaxial pattern 220E may be formed by epitaxial growth from the second sacrificial film SL2. The second epitaxial pattern 220E may surround the alternately laminated second sacrificial film SL2 and the second active pattern AP2.

According to some example embodiments, the first epitaxial pattern 120E may include a first part epitaxial pattern 121E and a second part epitaxial pattern 122E. The first part epitaxial pattern 121E may surround the first active portion AP1a. The second part epitaxial pattern 122E may surround the second active portion AP1b.

According to some example embodiments, the second epitaxial pattern 220E may include a third part epitaxial pattern 221E and a fourth part epitaxial pattern 222E. The third part epitaxial pattern 221E may surround the third active portion AP2a. The fourth part epitaxial pattern 222E may surround the fourth active portion AP2b.

According to some example embodiments, the first epitaxial pattern 120E and the second epitaxial pattern 220E may have crystal planes corresponding to the crystal planes of the substrate 100. For example, when the upper surface of the substrate 100 has a (110) crystal plane and the notch of the substrate 100 has a [100] crystal direction, the first epitaxial pattern 120E and the second epitaxial pattern 220E may have (100) crystal plane and (111) crystal plane. In another example embodiment, when the upper surface of the substrate 100 has a (100) crystal plane and the notch of the substrate 100 has a [110] crystal direction, the first epitaxial pattern 120E and the second epitaxial pattern 220E may have (111) crystal plane. In another example embodiment, when the upper surface of the substrate 100 has a (100) crystal plane and the notch of the substrate 100 has a [100] crystal direction, the first epitaxial pattern 120E and the second epitaxial pattern 220E may have (100) crystal plane.

According to some example embodiments, the (100) crystal planes of the first epitaxial pattern 120E and the second epitaxial pattern 220E may be parallel in the first direction D1. The (111) crystal planes of the first epitaxial pattern 120E and the second epitaxial pattern 220E intersect the first direction D1 and the third direction D3, and may be tilted with respect to the first direction D1.

According to some example embodiments, the first part epitaxial pattern 121E and the second part epitaxial pattern 122E may not be in contact with the first insulation column 310. The first part epitaxial pattern 121E and the second part epitaxial pattern 122E are formed by epitaxial growth from the first sacrificial film SL1, and thus the first part epitaxial pattern 121E and the second part epitaxial pattern 122E may not be formed on the first insulation column 310 including the insulating material. The first part epitaxial pattern 121E and the second part epitaxial pattern 122E may include facet surfaces intersecting at a desired and/or alternatively predetermined angle between the first insulation column 310 protruding upward from the first active pattern AP1 and the top first active pattern AP1.

According to some example embodiments, the third part epitaxial pattern 221E and the fourth part epitaxial pattern 222E may not be in contact with the second insulation column 320. The third part epitaxial pattern 221E and the fourth part epitaxial pattern 222E are formed by epitaxial growth from the second sacrificial film SL2, and thus the third part epitaxial pattern 221E and the fourth part epitaxial pattern 222E may not be formed on the second insulation column 320 containing the insulating material. The third part epitaxial pattern 221E and the fourth part epitaxial pattern 222E may include facet surfaces intersecting at a desired and/or alternatively predetermined angle between the second insulation column 320 protruding upward from the second active pattern AP2 and the top second active pattern AP2.

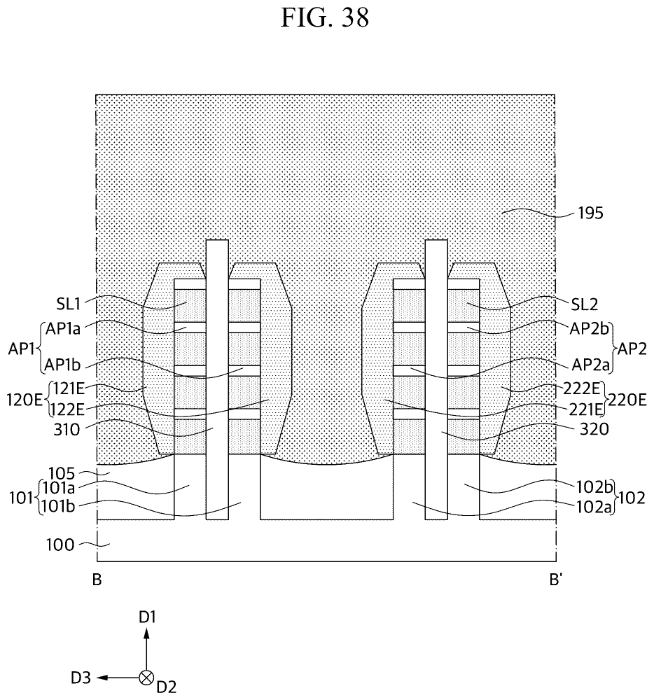

Referring to FIG. 38, the protection film 195 may be formed. The protection film 195 may be formed on the first epitaxial pattern 120E and the second epitaxial pattern 220E. For example, the protection film 195 may contain carbon-based materials. The protection film 195 may include at least one of a photoresist film, an amorphous carbon layer (ACL), a spin on hardmask (SOH), a Spin on Carbon (SOC), and a silicon nitride film.

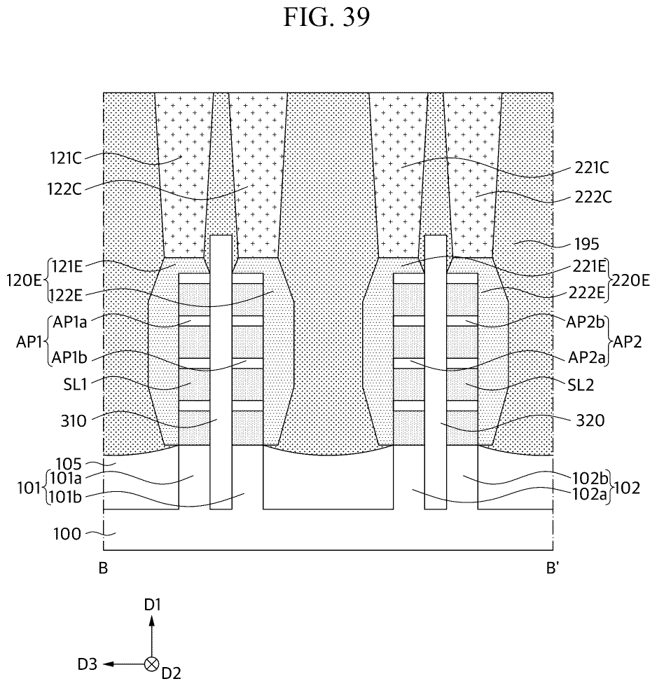

Referring to FIG. 39, a first part contact 121C, a second part contact 122C, a third part contact 221C and a fourth part contact 222C may be formed. The first part contact 121C and the second part contact 122C may be formed on the first epitaxial pattern 120E by penetrating a portion of the protection film 195. The third part contact 221C and the fourth part contact 222C may be formed on the second epitaxial pattern 220E by penetrating a portion of the protection film 195.

According to some example embodiments, the first part contact 121C may be formed on the first part epitaxial pattern 121E. The second part contact 122C may be formed on the second part epitaxial pattern 122E. The first part contact 121C and the second part contact 122C may be spaced apart by the first insulation column 310.

According to some example embodiments, the third part contact 221C may be formed on the third part epitaxial pattern 221E. The fourth part contact 222C may be formed on the fourth part epitaxial pattern 222E. The third part contact 221C and the fourth part contact 222C may be spaced apart by the second insulation column 320.

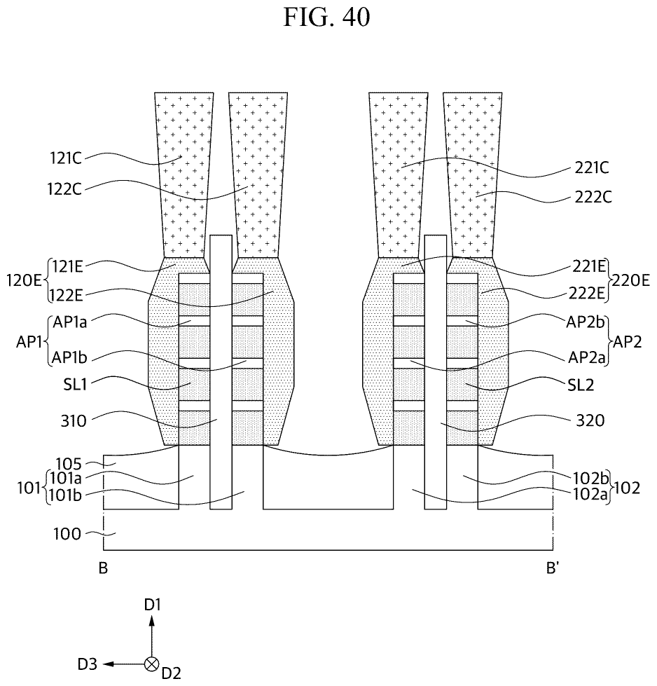

Referring to FIG. 40, the protection film 195 (of FIG. 39) may be removed. When the protection film 195 (of FIG. 39) is removed, the first part contact 121C, the second part contact 122C, the third part contact 221C, the fourth part contact 222C, the first epitaxial pattern 120E, the second epitaxial pattern 220E, and the device isolation film 105 may be exposed.

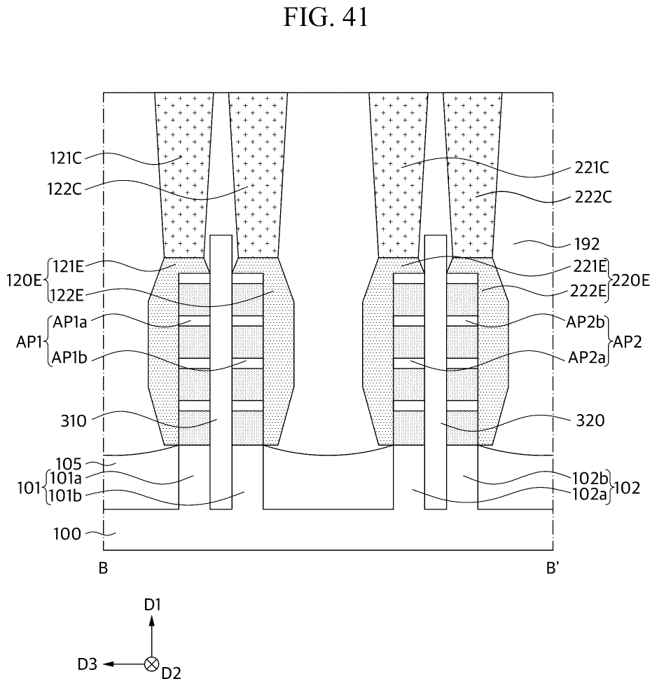

Referring to FIG. 41, the second interlayer insulation film 192 may be formed. The second interlayer insulation film 192 may cover the first part contact 121C, the second part contact 122C, the third part contact 221C, the fourth part contact 222C, the first epitaxial pattern 120E, the second epitaxial pattern 220E, and the device isolation film 105. The second interlayer insulation film 192 may surround the first part contact 121C, the second part contact 122C, the third part contact 221C, the fourth part contact 222C, and the first epitaxial pattern 120E and the second epitaxial pattern 220E.

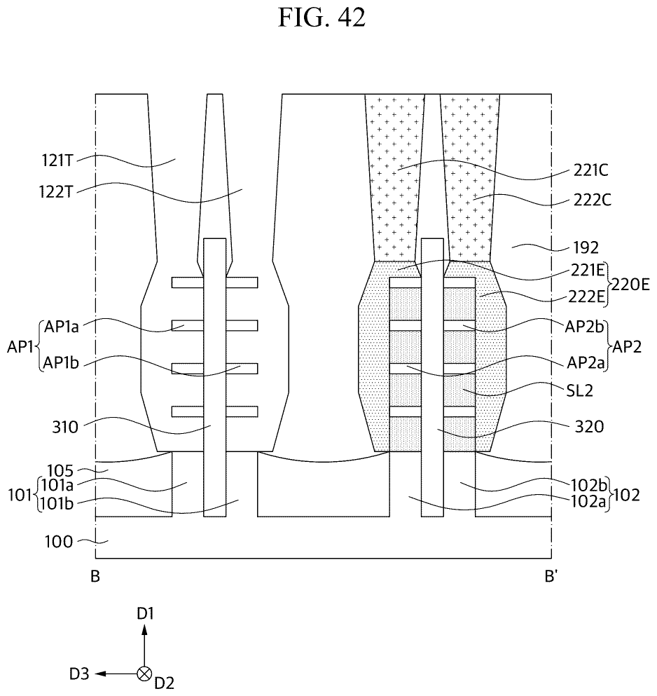

Referring to FIG. 42, the first sacrificial film SL1 (of FIG. 41), the first epitaxial pattern 120E (of FIG. 41), the first part contact 121C (of FIG. 41) and the second part contact 122C (of FIG. 41) may be removed. The first sacrificial film SL1 (FIG. 41), the first part epitaxial pattern 121E (FIG. 41) and the first part contact 121C (FIG. 41) may be removed to form a first gate part trench 121T. The second gate part trench 122T may be formed when the first sacrificial film SL1 (FIG. 41), the second part epitaxial pattern 122E (FIG. 41) and the second part contact 122C (FIG. 41) are removed. The first active pattern AP1 may be exposed within the first gate part trench 121T and the second gate part trench 122T.

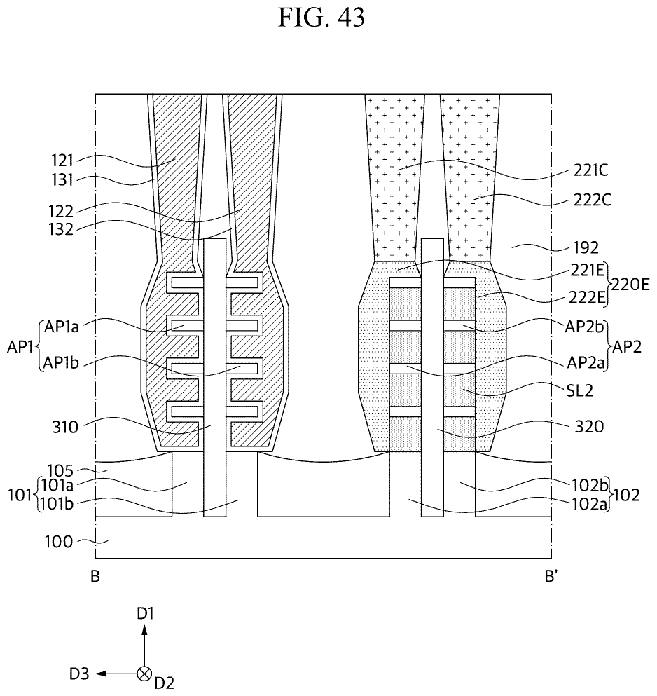

Referring to FIG. 43, the first part insulation film 131, the second part insulation film 132, the first gate part 121, and the second gate part 122 may be formed.

According to some example embodiments, the first part insulation film 131 and the first gate part 121 may be formed within the first gate part trench 121T (of FIG. 42). The first part insulation film 131 may surround the first active portion AP1a. The first part insulation film 131 may extend along the bottom and side surfaces of the first gate part trench 121T (of FIG. 42) and the side surface of the first insulation column 310. The first gate part 121 may fill the first gate part trench 121T (of FIG. 42) on the first part insulation film 131.

According to some example embodiments, the second part insulation film 132 and the second gate part 122 may be formed within the second gate part trench 122T (of FIG. 42). The second part insulation film 132 may surround the second active portion AP1b. The second part insulation film 132 may extend along the bottom and side surfaces of the second gate part trench 122T (of FIG. 42) and the side surface of the first insulation column 310. The second gate part 122 may fill the second gate part trench 122T (FIG. 42) on the second part insulation film 132.

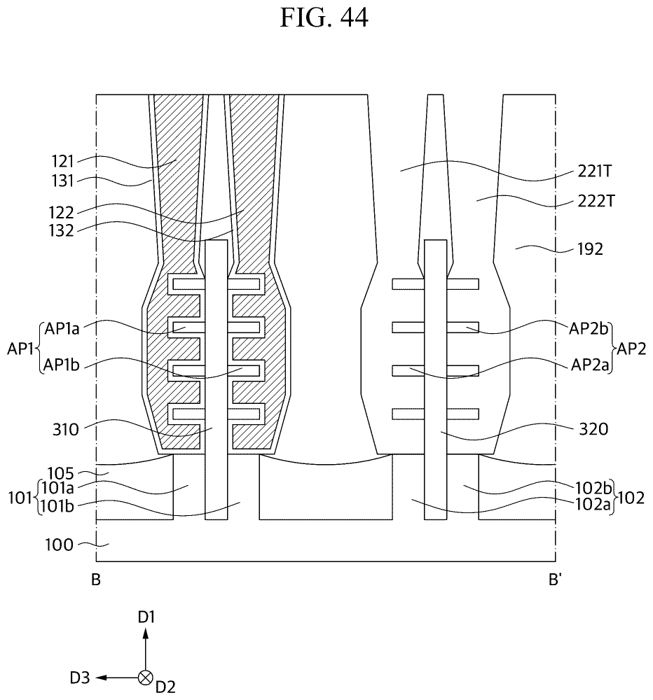

Referring to FIG. 44, the second sacrificial film SL2 (of FIG. 43), the second epitaxial pattern 220E (of FIG. 43), the third part contact 221C (of FIG. 43), and the fourth part contact 222C (of FIG. 43) may be removed. A third gate part trench 221T may be formed when the second sacrificial film SL2 (of FIG. 43), the third part epitaxial pattern 221E (of FIG. 43) and the third part contact 221C (of FIG. 43) are removed. A fourth gate part trench 222T may be formed when the second sacrificial film SL2 (of FIG. 43), the fourth part epitaxial pattern 222E (of FIG. 43), and the fourth part contact 222C (of FIG. 43) are removed. The second active pattern AP2 may be exposed within the third gate part trench 221T and the fourth gate part trench 222T.

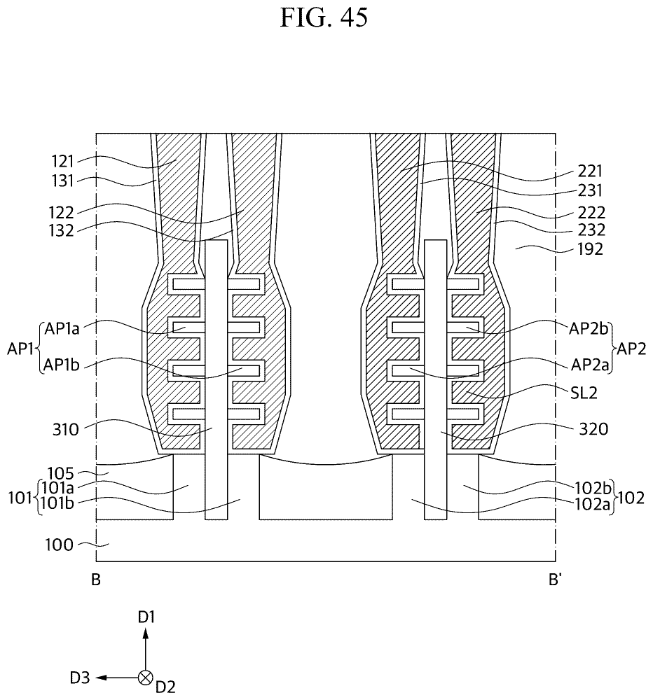

Referring to FIG. 45, the third part insulation film 231, the fourth part insulation film 232, the third gate part 221, and the fourth gate part 222 may be formed.

According to some example embodiments, the third part insulation film 231 and the third gate part 221 may be formed within the third gate part trench 221T (of FIG. 44). The third part insulation film 231 may surround the third active portion AP2a. The third part insulation film 231 may extend along the bottom and side surfaces of the third gate part trench 221T (of FIG. 44) and the side surface of the second insulation column 320. The third gate part 221 may fill the third gate part trench 221T (of FIG. 44) on the third part insulation film 231.

According to some example embodiments, the fourth part insulation film 232 and the fourth gate part 222 may be formed within the fourth gate part trench 222T (of FIG. 44). The fourth part insulation film 232 may surround the fourth active portion AP2b. The fourth part insulation film 232 may extend along the bottom and side surfaces of the fourth gate part trench 222T (of FIG. 44) and the side surface of the second insulation column 320. The fourth gate part 222 may fill the fourth gate part trench 222T (of FIG. 44) on the fourth part insulation film 232.

Referring to FIG. 9, the first etching stopping film 193 and the third interlayer insulation film 194 may be formed on the second interlayer insulation film 192, and the interconnection via 175 may be formed on the first gate part 121, the second gate part 122, the third gate part 221, and the fourth gate part 222.

According to an example embodiment, a method of manufacturing a semiconductor device may include forming a plurality of first active patterns, a plurality of first source/drain patterns, a plurality of second active patterns, and a plurality of second source/drain patterns on a substrate, the plurality of first active patterns being spaced apart from each other in a first direction, the first direction intersecting an upper surface of the substrate, the plurality of first active patterns extending in a second direction, the second direction intersecting the first direction, the plurality of first source/drain patterns extending in the first direction and being spaced apart from each other in the second direction, the plurality of first source/drain patterns being connected to opposite sides of the plurality of first active patterns in the second direction, the plurality of second active patterns being spaced apart from the plurality of first active patterns in a third direction, the third direction intersecting the first direction and the second direction, the plurality of second source/drain patterns extending in the first direction and being spaced apart from each other in the second direction, the plurality of second source/drain patterns being connected to opposite sides of the plurality of second active patterns in the second direction, the plurality of first source/drain patterns being spaced apart from the plurality of second source/drain patterns in the third direction; forming a gate separation structure on the substrate between the plurality of first active patterns and the plurality of second active patterns in the third direction; forming a first gate electrode surrounding at least a portion of the plurality of first active patterns; and forming a second gate electrode surrounding at least a portion of the plurality of second active patterns, wherein the first gate electrode and the second gate electrode may be formed after the gate separation structure and formed spaced apart from opposite sides of the gate separation structure such that the gate separation structure may be between the first gate electrode and the second gate electrode in the third direction, the first gate electrode may include a first lower portion pattern and a first upper portion pattern on the first lower portion pattern, the first lower portion pattern may surround the plurality of first active patterns and may protrude outward from a center of one of the plurality of first active patterns in the third direction, a width of the first upper portion pattern in the third direction may increase as the first upper portion pattern gets farther from the first lower portion pattern in the first direction, the second gate electrode may include a second lower portion pattern and a second upper portion pattern on the second lower portion pattern, the second lower portion pattern may surround the plurality of second active patterns and protruding outward from a center of one of the plurality of second active patterns in the third direction, and a width of the second upper portion pattern in the third direction may increase as the second upper portion pattern gets farther from the second lower portion pattern in the first direction.

In some embodiments, a side surface of the first lower portion pattern in the third direction and a side surface of the second lower portion pattern in the third direction each may include a facet surface.

In some embodiments, the method may further include: forming a first fin pattern, forming a second fin pattern in the substrate, and forming a device isolation film on the substrate before forming the plurality of first active patterns, the plurality of first source/drain patterns, the plurality of second active patterns, and the plurality of second source/drain patterns on the substrate. The first fin pattern and the second fin pattern may protrude from the substrate in the first direction through the device isolation film. The first fin pattern and the second fin pattern may extend in the second direction and may be spaced apart from each other in the first direction. The plurality of first active patterns may be formed on top of the first fin pattern and the plurality of second active patterns are formed on top of the second fin pattern. The forming the first gate electrode and the forming the second gate electrode may include forming a first gate insulation film surrounding the first gate electrode and forming a second gate insulation film surrounding the second gate electrode. A portion of a lower surface of the first gate insulation film and a portion of a lower surface of the second gate insulation film may not be in contact with an upper surface of the device isolation film below the portion of the lower surface of the first gate insulation film and the portion of the lower surface of the second gate insulation film.

In some embodiments, the first gate insulation film may extend along a side surface of the first lower portion pattern, a lower surface of the first lower portion pattern, and a side surface of the first upper portion pattern.

In some embodiments, the first gate insulation film may cover a first side surface of the gate separation structure facing the first gate electrode in the third direction, and the second gate insulation film may cover a second side surface of the gate separation structure facing the second gate electrode in the third direction.

While some example embodiments have been described with reference to the accompanying drawings above, the present disclosure is not limited to the above example embodiments and may be manufactured in various forms different from each other. Those skilled in the art to which the present disclosure belongs may understand that other embodiments may be implemented without changing the technical spirit or characteristics of the present disclosure. Therefore, in all aspects, the above-described example embodiments should be understood as non-limiting examples.

1. A semiconductor device comprising:
a plurality of first source/drain patterns on a substrate in a first direction and being spaced apart from each other in a second direction, the first direction intersecting an upper surface of the substrate and the second direction intersecting the first direction;
a first gate electrode between the plurality of first source/drain patterns;
a first active pattern penetrating the first gate electrode in the second direction, the first active pattern being connected with the plurality of first source/drain patterns;
a plurality of second source/drain patterns spaced apart from the plurality of first source/drain patterns in a third direction, the third direction intersecting the first direction and the second direction;
a second gate electrode spaced apart from the first gate electrode in the third direction, the second gate electrode being between the plurality of second source/drain patterns in the second direction; and
a second active pattern penetrating the second gate electrode in the second direction, the second active pattern being connected with the plurality of second source/drain patterns,
wherein a first side surface of the first gate electrode in the third direction and a second side surface of the second gate electrode in the third direction each comprise a facet surface.

2. The semiconductor device of claim 1, further comprising:
a gate separation structure between the first side surface of the first gate electrode and the second side surface of the second gate electrode, wherein
the first side surface of the first gate electrode and the second side surface of the second gate electrode face each other in the third direction.

3. The semiconductor device of claim 2, wherein
a first part of the gate separation structure comprises a lower surface of the gate separation structure in the first direction,
the first part of the gate separation structure is between a lowest facet surface of the first side surface of the first gate electrode and a lowest facet surface of the second side surface of the second gate electrode, and
a width of the first part decreases as the gate separation structure gets farther from the substrate in the first direction.

4. The semiconductor device of claim 2, further comprising:
a first gate insulation film surrounding the first gate electrode and extending along the first side surface of the first gate electrode; and
a second gate insulation film surrounding the second gate electrode and extending along the second side surface of the second gate electrode.

5. The semiconductor device of claim 4, wherein a side surface of the gate separation structure in the third direction is covered by the first gate insulation film and the second gate insulation film.

6. The semiconductor device of claim 2, further comprising:
a device isolation film on the substrate and under the gate separation structure, wherein
in a plan view, the device isolation film is between the first active pattern and the second active pattern in the third direction.

7. The semiconductor device of claim 6, wherein the gate separation structure is in contact with an upper surface of the device isolation film.

8. The semiconductor device of claim 1, wherein a portion of a region of the first side surface of the first gate electrode and a portion of a region of the second side surface of the second gate electrode are parallel in the first direction.

9. The semiconductor device of claim 1, wherein
the first gate electrode comprises a first lower portion pattern and a first upper portion pattern on the first lower portion pattern in the first direction,
the first lower portion pattern surrounds the first active pattern, and
a width of the first upper portion pattern in the third direction gets wider as the first upper portion pattern gets farther from the substrate in the first direction, and
a width of the first lower portion pattern in the third direction that gets wider and then narrower as the first lower portion pattern gets farther from the substrate in the first direction.

10. The semiconductor device of claim 1, wherein
the first active pattern comprises a plurality of first sheets that are stacked in the first direction, and
the second active pattern comprises a plurality of second sheets that are stacked in the first direction.

11. The semiconductor device of claim 1, wherein
in the first side surface of the first gate electrode, the facet surface is aligned with a crystal plane of the plurality of first source/drain patterns, or
in the second side surface of the second gate electrode, the facet surface is aligned with a crystal plane of the plurality of second source/drain patterns.

12. A semiconductor device comprising:
a first active pattern over a substrate in a first direction, the first direction intersecting an upper surface of the substrate, the first active pattern extending in a second direction, the second direction intersecting the first direction;
a first gate electrode surrounding at least a portion of the first active pattern;
a second active pattern over the substrate in the first direction, the second active pattern being spaced apart from the first active pattern in a third direction, the third direction intersecting the first direction and the second direction;
a second gate electrode spaced apart from the first gate electrode in the third direction and surrounding at least a portion of the second active pattern; and
a gate separation structure between the first gate electrode and the second gate electrode in the third direction, wherein
the first gate electrode comprises a first lower portion pattern and a first upper portion pattern on the first lower portion pattern,
the first lower portion pattern surrounds the first active pattern and protrudes outward from a center of the first active pattern in the third direction,
a width of the first upper portion pattern in the third direction increases as the first upper portion pattern gets farther from the first lower portion pattern in the first direction,
the second gate electrode comprises a second lower portion pattern and a second upper portion pattern on the second lower portion pattern,
the second lower portion pattern surrounds the second active pattern and protruding outward from a center of the second active pattern in the third direction, and
a width of the second upper portion pattern in the third direction increases as the second upper portion pattern gets farther from the second lower portion pattern in the first direction.

13. The semiconductor device of claim 12, wherein
a side surface of the first lower portion pattern in the third direction and a side surface of the second lower portion pattern in the third direction each comprise a facet surface.

14. The semiconductor device of claim 12, further comprising:
a device isolation film on the substrate by a lower portion of the gate separation structure, the device isolation film being between the first active pattern and the second active pattern in the third direction;
a first gate insulation film surrounding the first gate electrode; and
a second gate insulation film surrounding the second gate electrode, wherein
a lower surface of the first gate insulation film and a lower surface of the second gate insulation film are not in contact with an upper surface of the device isolation film.

15. The semiconductor device of claim 14, wherein the first gate insulation film extends along a side surface of the first lower portion pattern, a lower surface of the first lower portion pattern and a side surface of the first upper portion pattern.

16. The semiconductor device of claim 14, wherein
the first gate insulation film covers a first side surface of the gate separation structure facing the first gate electrode in the third direction, and
the second gate insulation film covers a second side surface of the gate separation structure facing the second gate electrode in the third direction.

17. The semiconductor device of claim 12, wherein
a first inner side of the first active pattern faces the second active pattern in the third direction,
a first outer side of the first active pattern is opposite the first inner side of the first active pattern in the third direction, and
a thickness in the third direction of a portion of the first gate electrode on the first outer side of the first active pattern in the third direction is identical to a thickness in the third direction of a portion of the first gate electrode on the first inner side of the first active pattern in the third direction.

18. The semiconductor device of claim 17, wherein
a second inner side of the second active pattern faces the first active pattern in the third direction,
a second outer side of the second active pattern is opposite the second inner side of the second active pattern in the third direction, and
a thickness in the third direction of a portion of the second gate electrode on the second outer side of the second active pattern in the third direction is identical to the thickness in the third direction of the portion of the first gate electrode on the first outer side of the first active pattern in the third direction.

19. The semiconductor device of claim 12, further comprising:
a first source/drain pattern spaced apart from the first gate electrode in the second direction, wherein
the first source/drain pattern is connected with the first active pattern in the second direction.

20. A semiconductor device comprising:
a plurality of first source/drain patterns on a substrate in a first direction and being spaced apart from each other in a second direction, the first direction intersecting an upper surface of the substrate, and the second direction intersecting the first direction;
a first gate electrode between the plurality of first source/drain patterns in the second direction;
a first gate insulation film surrounding a lower surface of the first gate electrode and a side surface of the first gate electrode;
a first active pattern penetrating the first gate electrode in the second direction, the first active pattern being connected with the plurality of first source/drain patterns;
a plurality of second source/drain patterns spaced apart from the plurality of first source/drain patterns in a third direction, the third direction intersecting the first direction and the second direction;
a second gate electrode spaced apart from the first gate electrode in the third direction, the second gate electrode being between the plurality of second source/drain patterns in the second direction;
a second gate insulation film surrounding a lower surface of the second gate electrode and a side surface of the second gate electrode; and
a second active pattern penetrating the second gate electrode in the second direction, the second active pattern being connected with the plurality of second source/drain patterns, wherein
a first side surface of the first gate electrode in the third direction and a second side surface of the second gate electrode in the third direction each include a facet surface having a (100) crystal plane.

21. (canceled)
